(19) United States
(12) Patent Application Publication
(10) Pub. No.: US 2021/0083131 A1
(43) Pub. Date: Mar. 18, 2021

(54) END SURFACE INCIDENT-TYPE LIGHT RECEIVING ELEMENT

(71) Applicant: KYOTO SEMICONDUCTOR CO., LTD., Kyoto-shi, Kyoto (JP)

(72) Inventors: Etsuji OMURA, Kyoto-shi (JP); Takatomo ISOMURA, Kyoto-shi (JP); Ken USUI, Kyoto-shi (JP)

(73) Assignee: KYOTO SEMICONDUCTOR CO., LTD., Kyoto-shi, Kyoto (JP)

(21) Appl. No.: 16/643,406

(22) PCT Filed: Aug. 31, 2017
(86) PCT No.: PCT/JP2017/031339

§ 371 Date: Feb. 28, 2020

(51) Int. Cl. H01L 31/0232; F21S 41/24

(52) U.S. Cl. CPC H01L 31/0232; F21Y 2115/10; F21S 41/24

(57) ABSTRACT

An end surface incident-type light receiving element according to an aspect of the present disclosure is made of a semiconductor material, and includes an upper surface and a lower surface that are opposite to each other in the vertical direction, and an end surface that couples the upper surface and the lower surface and is to be arranged on a light source side, the light source side being a side from which the light source emits light. At least a portion of the end surface is inclined relative to the vertical direction such that the lower surface side is arranged closer to the light source than the upper surface side is. The lower surface is provided with one or more grooves. The inclined surfaces on the end surface side of one or more grooves are arranged so as to reflect incident light that is emitted from the light source and passes through the end surface. A light receiving region for receiving the light reflected by the inclined surfaces on the end surface side of the one or more grooves is provided on the upper surface side.

### TECHNICAL FIELD

The present invention relates to an end surface incident-type light receiving element.

### BACKGROUND ART

A semiconductor laser is used as a light source for optical communication, and a light receiving element is used to continuously monitor light emitted from the back surface of the semiconductor laser for the purpose of keeping optical output stable. Conventionally, a so-called surface incident-type light receiving element in which light is incident on the principal surface of the semiconductor at a right angle has been used for such monitoring.

However, in order to achieve a configuration in which a surface incident-type light receiving element receives a laser beam emitted from the back surface of a semiconductor laser, the axis of the laser beam needs to intersect the light receiving surface at a right angle. For this purpose, the light receiving element is mounted on a sub-mount, and the sub-mount is rotated 90 degrees. In other words, when a surface incident-type light receiving element is used, the light receiving element needs to be mounted while being placed against the back surface of the semiconductor laser. Accordingly, there is a problem in that it is difficult to reduce the size of the overall device due to an increase in the number of components by the sub-mount and the like.

To address this, Patent Literature 1 and 2 and Non-Patent Literature 1 propose an end surface incident-type light receiving element having a configuration in which an optical axis of incident light is set to be parallel with the optical axis of a laser beam emitted from the back surface of a semiconductor laser. With this end surface incident-type light receiving element, a configuration in which the optical axis of a laser beam intersects the light-receiving surface (end surface) at a right angle can be achieved without using a sub-mount. Accordingly, it is possible to prevent an increase in the number of components and to reduce the size of the overall device.

### CITATION LIST

### Patent Literature

Patent Literature 1: JP H11-087760A
Patent Literature 2: JP 2000-228531A

### Non-Patent Literature

Non-Patent Literature 1: Tadatoshi Tomimoto, “Development of 10 Gbit/s Surface Mount Module Using End Surface Incident-Type PIN PD”, OKI Technical Reviews, 196, Vol. 70 No. 4, October 2003, p. 100-103

### SUMMARY OF INVENTION

### Technical Problem

Problems of an end surface incident-type light receiving element according to a conventional example will be described with reference to FIGS. 1A to 1C. FIG. 1A is a schematic cross-sectional view illustrating an end surface incident-type light receiving element 1000 according to a conventional example. FIGS. 1B and 1C schematically illustrate states in which the end surface incident-type light receiving element 1000 according to the conventional example receives a laser beam 1052. It should be noted that the following description illustrates an end surface incident-type light receiving element made of InP (indium phosphide)-based semiconductors.

As shown in FIG. 1A, the end surface incident-type light receiving element 1000 according to the conventional example includes an n-type InP substrate 1001, an active layer 1002 provided on a principal surface of the n-type InP substrate 1001, and an n-type InP layer 1003 provided on the active layer 1002. The active layer 1002 is made of n-type InGaAs (indium gallium arsenide), for example. The active layer 1002 and the n-type InP layer 1003 are formed through epitaxial growth or the like, for example.

Zn (zinc) and the like is diffused in a portion of the n-type InP layer 1003, and thus a p-type diffusion region (p-type InP region) 1004 is formed. A portion including a PN junction that is formed directly underneath the p-type diffusion region 1004 serves as an active region (light receiving portion) 1005 that receives light.

The end surface incident-type light receiving element 1000 according to the conventional example is formed with a substantially rectangular cross section and includes an upper surface 1011 and a lower surface 1012 that are opposed to each other in a vertical direction. Also, the end surface incident-type light receiving element 1000 according to the conventional example includes an end surface 1013 that is arranged on a side from which light such as a laser beam is incident, and a back surface 1014 that is opposed to this end surface in a horizontal direction.

The n-type InP substrate 1001 is provided with a groove 1021 with a substantially reversed V-shaped cross-section on the lower surface 1012 side through etching or the like. The groove 1021 includes an inclined surface 1022 that is arranged on the end surface 1013 side, and an upper end 1023 that is closest to the upper surface 1011. It should be noted that a p-type electrode 1008 is provided on the p-type diffusion region 1004 on the upper surface 1011 side, and an n-type electrode 1009 is correspondingly provided on the lower surface 1012 as appropriate.

The end surface incident-type light receiving element 1000 operates as follows. As shown in FIGS. 1B and 1C, the end surface incident-type light receiving element 1000 is arranged such that the end surface 1013 opposes a light source. In other words, a semiconductor laser device 1050 serving as a light source is arranged at a position that is opposite to the end surface 1013 and near the end surface incident-type light receiving element 1000. The semiconductor laser device 1050 is configured to emit the laser beam 1052 from a light emitting point 1051.

The laser beam 1052 emitted from the semiconductor laser device 1050 enters the n-type InP substrate 1001 through the end surface 1013 and is incident on the inclined surface 1022 of the groove 1021. The inclined surface 1022 reflects, toward the upper surface 1011 side, the incident laser beam 1052 that has passed through the end surface 1013 in accordance with the law of reflection. In other words, the optical path of the laser beam 1052 is bent by the inclined surface 1022. Accordingly, the laser beam 1052 reaches the active region 1005 and thus a photoelectric current is generated in the active region 1005. A light receiving element configured such that incident light is not introduced thereinto through the principal surface of the substrate (upper surface side) but through an end surface as described above is an end surface incident-type light receiving element.

Here, in a normal case, the light emitting point 1051 of the semiconductor laser device 1050 is arranged at a position at a height of 100 μm to 120 μm from the lower surface 1012 of the end surface incident-type light receiving element 1000. In general, the laser beam 1052 emitted from the light emitting point 1051 travels in a straight line while being slightly diffused.

In the example shown in FIG. 1B, the height from the lower surface 1012 to the active region 1005 is set to 200 μm. Furthermore, the height from the lower surface 1012 to the light emitting point 1051 is set to 100 μm, whereas the depth of the groove 1021, namely the height from the lower surface 1012 to the upper end 1023, is set to 120 μm.

In this case, as shown in FIG. 1B, although the laser beam 1052 is slightly diffused, almost all of the laser beam 1052 entering through the end surface 1013 is incident on the inclined surface 1022 of the groove 1021 because the upper end 1023 of the groove 1021 is arranged at a position that is sufficiently higher than the light emitting point 1051, in other words, the groove 1021 is sufficiently deep. Accordingly, a configuration can be achieved in which almost all of the laser beam 1052 entering through the end surface 1013 is reflected by the inclined surface 1022 and reaches the active region 1005 serving as a light receiving portion.

On the other hand, in the example shown in FIG. 1C, the configuration of the end surface incident-type light receiving element 1000 remains the same as that of the example shown in FIG. 1B, but the height from the lower surface 1012 to the light emitting point 1051 is changed to 120 μm. In other words, the height to the light emitting point 1051 is equal to the depth of the groove 1021. In this case, as shown in FIG. 1C, after the laser beam 1052 has entered the n-type InP substrate 1001 through the end surface 1013, a portion of the laser beam 1052 that diffuses upward is not incident on the inclined surface 1022 of the groove 1021 and passes over the upper end 1023.

Therefore, the portion of the laser beam 1052 that diffuses upward travels toward the back surface 1014 and cannot reach the active region 1005 serving as a light receiving portion. Accordingly, in this case, the photoelectric conversion efficiency (i.e., sensitivity of the end surface incident-type light receiving element 1000) decreases by a portion of the laser beam 1052 that does not reach the active region 1005. If the height to the light emitting point 1051 is equal to the depth of the groove 1021, about half of the laser beam 1052 emitted from the light emitting point 1051 is not reflected by the inclined surface 1022 and travels toward the back surface 1014, and therefore, the photoelectric conversion efficiency decreases by about 50%.

Therefore, the larger the height to the light emitting point 1051 is, the lower the sensitivity of the end surface incident-type light receiving element 1000 is. Such a decrease in sensitivity can be prevented by making the groove 1021 deeper. However, making the groove 1021 deeper poses problems as shown in FIGS. 1D and 1E.

FIG. 1D is a schematic perspective view illustrating the end surface incident-type light receiving element 1000 according to the conventional example. FIG. 1E schematically illustrates the end surface incident-type light receiving element 1000 according to the conventional example, as viewed from the end surface 1013 (i.e., light receiving surface) side. In general, the groove 1021 is formed using an anisotropic etching solution. A bromomethanol solution is often used to etch an InP-based semiconductor.

When anisotropic etching is performed, the etching speed varies depending on the crystal orientation. Therefore, as shown in FIGS. 1D and 1E, the length in the width direction (a direction orthogonal to the plane of FIG. 1A; the left-right direction in FIG. 1E) of the groove 1021 increases toward the upper end 1023. In other words, the width of the groove 1021 increases from the lower surface 1012 as the depth thereof increases.

As a result, the end portions of the upper end 1023 in the width direction of the groove 1021 are located near the side walls of the end surface incident-type light receiving element 1000 (n-type InP substrate 1001), and the thicknesses of portions 1031 between the groove 1021 and the side walls decrease. This makes the end surface incident-type light receiving element 1000 mechanically vulnerable.

To address this problem, it is conceivable that increasing the length in the width direction of the end surface incident-type light receiving element 1000 will make it possible to ensure the mechanical strength of the end surface incident-type light receiving element 1000 even when the groove 1021 is made deeper. However, when the length in the width direction of the end surface incident-type light receiving element 1000 is increased, the size of the end surface incident-type light receiving element 1000 is increased, and thus the size of the end surface incident-type light receiving element 1000 cannot be reduced.

One aspect of the present invention has been made in view of such circumstances, and it is an object thereof to provide an end surface incident-type light receiving element that can be reduced in size without impairing the mechanical strength and has improved photoelectric conversion efficiency.

### Solution to Problem

The present invention employs the following configuration in order to solve the above-described problem.

In other words, an end surface incident-type light receiving element made of a semiconductor material according to one aspect of the present disclosure includes: an upper surface and a lower surface that are opposite to each other in a vertical direction; and an end surface that couples the upper surface and the lower surface and is to be arranged on a light source side, the side being a side from which the light source emits light, wherein at least a portion of the end surface is inclined relative to the vertical direction in a state in which a portion on the lower surface side of the inclined portion is arranged closer to the light source than a portion on the upper surface side of the inclined portion is, the lower surface is provided with one or more grooves, inclined surfaces on the end surface side of the one or more grooves are arranged so as to reflect incident light that is emitted from the light source and passes through the end surface, and a light receiving region for receiving the light reflected by the inclined surfaces on the end surface side of the one or more grooves is provided on the upper surface side.

In the end surface incident-type light receiving element according to the above-mentioned configuration, at least a portion of the end surface arranged on the light source side is inclined relative to the vertical direction such that the lower surface side is closer to the light source than the upper surface side is. With this configuration, light such as a laser beam emitted from a light source can be refracted toward the lower surface by this inclined portion when the light enters the end surface incident-type light receiving element through the end surface. In other words, this inclined portion of the end surface can bend the optical path of the light emitted from the light source toward the lower surface provided with one or more grooves.

Accordingly, a configuration can be achieved in which light entering the end surface incident-type light receiving element is reflected by the inclined surfaces of one or more grooves and reaches the light receiving region even if the height to the light emitting point of the light source is larger than the heights to the upper ends of one or more grooves. Therefore, it is possible to suppress a decrease in the photoelectric conversion efficiency without making one or more grooves deeper. Since it is possible to reduce the depths of one or more grooves while suppressing a decrease in the photoelectric conversion efficiency, it is possible to ensure the mechanical strength of the end surface incident-type light receiving element even if the thickness in the width direction of the end surface incident-type light receiving element is reduced. Accordingly, with the above-mentioned configuration, it is possible to provide an end surface incident-type light receiving element that can be reduced in size without impairing the mechanical strength and has improved photoelectric conversion efficiency.

In the above-mentioned end surface incident-type light receiving element according to one aspect, the entire region of the end surface may be inclined relative to the vertical direction. With this configuration, the manufacturing process of an end surface incident-type light receiving element can be simplified.

In the above-mentioned end surface incident-type light receiving element according to one aspect, a portion on the upper surface side of the end surface may be inclined relative to the vertical direction, and the remainder of the end surface may be formed extending in the vertical direction. With this configuration, it is possible to provide an end surface incident-type light receiving element having improved photoelectric conversion efficiency.

In the above-mentioned end surface incident-type light receiving element according to one aspect, a lower end of the inclined portion on the upper surface side may be located at a position that is as high as upper ends of the one or more grooves or is higher than upper ends of the one or more grooves. With this configuration, it is possible to provide an end surface incident-type light receiving element having improved photoelectric conversion efficiency.

In the above-mentioned end surface incident-type light receiving element according to one aspect, an inclination angle A1 of the inclined portion on the upper surface side and inclination angles A2 of the inclined surfaces of the one or more grooves may be set to satisfy Formula 1 below.

$$Numerical Formula 1$$

$$A 2 \leq A 1 + {sin}^{- 1} ( \frac{{n}_{1}}{{n}_{2}} \cdot cos A 1 ) - {sin}^{- 1} ( \frac{{n}_{1}}{{n}_{2}} ) \qquad Formula 1$$

In this formula, n₁ indicates the absolute refractive index of air, and n₂ indicates the absolute refractive index of the semiconductor material.

With this configuration, the inclined surfaces of one or more grooves can fully reflect light entering through the inclined portion located on the upper surface side. Accordingly, it is possible to provide an end surface incident-type light receiving element having improved photoelectric conversion efficiency.

In the above-mentioned end surface incident-type light receiving element according to one aspect, the portion of the end surface that is inclined relative to the vertical direction may be formed in a flat shape. With this configuration, the manufacturing process of an end surface incident-type light receiving element can be simplified.

In the above-mentioned end surface incident-type light receiving element according to one aspect, the portion of the end surface that is inclined relative to the vertical direction may be formed in a curved shape to condense the incident light emitted from the light source on at least one of the inclined surfaces on the end surface side of the one or more grooves. With this configuration, light entering the end surface incident-type light receiving element through the end surface can be condensed on at least one of the inclined surfaces of one or more grooves. Accordingly, it is possible to provide an end surface incident-type light receiving element having improved photoelectric conversion efficiency.

In the above-mentioned end surface incident-type light receiving element according to one aspect, the lower surface may be provided with a plurality of the grooves, and the plurality of the grooves may be arranged in a direction in which the light is incident. Arranging, in the direction in which the light is incident, the plurality of grooves for reflecting light entering the end surface incident-type light receiving element toward the light receiving region makes it possible to further reduce the depths of the grooves while suppressing a decrease in the photoelectric conversion efficiency. Accordingly, with this configuration, it is possible to provide an end surface incident-type light receiving element that can be further reduced in size.

In the above-mentioned end surface incident-type light receiving element according to one aspect, a metal film may be formed on the outer sides of the inclined surfaces on the end surface side of the one or more grooves. With this configuration, it is possible to improve the reflectance of the inclined surfaces of one or more grooves, thus making it possible to provide an end surface incident-type light receiving element having improved photoelectric conversion efficiency.

### Advantageous Effects of the Invention

With the present disclosure, it is possible to provide an end surface incident-type light receiving element that can be reduced in size without impairing the mechanical strength and has improved photoelectric conversion efficiency.

### BRIEF DESCRIPTION OF DRAWINGS

FIG. 1A is a schematic cross-sectional view illustrating an end surface incident-type light receiving element according to a conventional example.

FIG. 1B schematically illustrates a state in which the end surface incident-type light receiving element according to the conventional example receives a laser beam.

FIG. 1C schematically illustrates a state in which the end surface incident-type light receiving element according to the conventional example receives a laser beam.

FIG. 1D is a schematic perspective view illustrating the end surface incident-type light receiving element according to the conventional example.

FIG. 1E schematically illustrates the end surface incident-type light receiving element according to the conventional example, as viewed from a light receiving surface (an end surface) side.

FIG. 2 is a schematic cross-sectional view illustrating an end surface incident-type light receiving element according to an embodiment.

FIG. 3A schematically illustrates a state in a manufacturing process of the end surface incident-type light receiving element according to the embodiment.

FIG. 3B schematically illustrates a state in the manufacturing process of the end surface incident-type light receiving element according to the embodiment.

FIG. 3C schematically illustrates a state in the manufacturing process of the end surface incident-type light receiving element according to the embodiment.

FIG. 3D schematically illustrates a state in the manufacturing process of the end surface incident-type light receiving element according to the embodiment.

FIG. 4 schematically illustrates a state in which the end surface incident-type light receiving element according to the embodiment receives a laser beam.

FIG. 5 schematically illustrates the end surface incident-type light receiving element according to the embodiment, as viewed from a light receiving surface (an end surface) side.

FIG. 6 is a schematic cross-sectional view illustrating an end surface incident-type light receiving element according to a modified example.

FIG. 7 schematically illustrates a state in which the end surface incident-type light receiving element according to the modified example receives a laser beam.

FIG. 8 is a diagram for describing a condition under which a laser beam is fully reflected by an inclined surface of a groove of the end surface incident-type light receiving element according to the modified example.

FIG. 9 is a schematic cross-sectional view illustrating an end surface incident-type light receiving element according to a modified example.

FIG. 10 schematically illustrates a state in which the end surface incident-type light receiving element according to the modified example receives a laser beam.

FIG. 11A schematically illustrates a state in the manufacturing process of the end surface incident-type light receiving element according to the modified example.

FIG. 11B schematically illustrates a state in the manufacturing process of the end surface incident-type light receiving element according to the modified example.

FIG. 11C schematically illustrates a state in the manufacturing process of the end surface incident-type light receiving element according to the modified example.

FIG. 11D schematically illustrates a state in the manufacturing process of the end surface incident-type light receiving element according to the modified example.

FIG. 11E schematically illustrates a state in the manufacturing process of the end surface incident-type light receiving element according to the modified example.

FIG. 12 schematically illustrates a state in the manufacturing process of the end surface incident-type light receiving element according to the modified example.

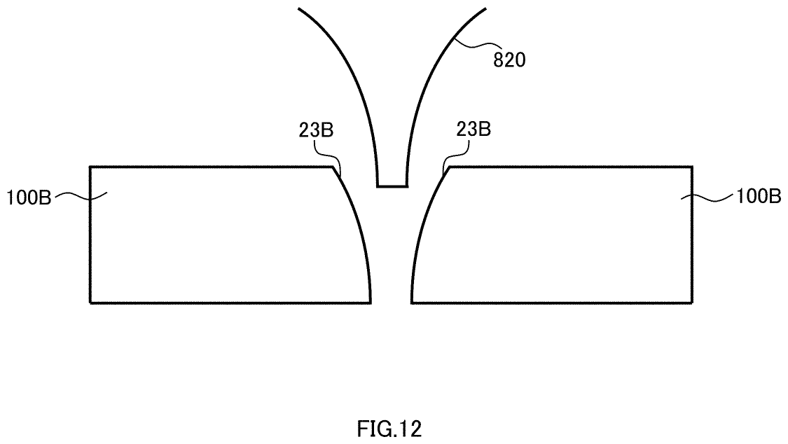

FIG. 13 is a schematic cross-sectional view illustrating an end surface incident-type light receiving element according to a modified example.

FIG. 14 schematically illustrates the end surface incident-type light receiving element according to the modified example, as viewed from a light receiving surface (an end surface) side.

FIG. 15 is a schematic cross-sectional view illustrating an end surface incident-type light receiving element according to a modified example.

FIG. 16 schematically illustrates a state in which the end surface incident-type light receiving element according to the modified example receives a laser beam.

FIG. 17 is a schematic cross-sectional view illustrating an end surface incident-type light receiving element according to a modified example.

FIG. 18 schematically illustrates a state in which the end surface incident-type light receiving element according to the modified example receives a laser beam.

FIG. 19 shows the results of a simulation for determining a coupling efficiency relative to the height to a light source that was performed on working examples and a comparative example.

FIG. 20 shows the results of a simulation for determining a coupling efficiency relative to the height to a light source that was performed on a working example and a comparative example.

FIG. 21A shows the results of a simulation for determining a coupling efficiency relative to the curvature radius of the end surface that was performed on a working example.

FIG. 21B shows the results of a simulation for determining a coupling efficiency relative to the curvature radius of the end surface that was performed on a working example.

FIG. 22 is a diagram for describing the details of a simulation.

FIG. 23 shows the result of a simulation for determining a light reaching position relative to a light source.

FIG. 24 is a diagram for describing the details of the simulation.

FIG. 25A shows the results of a simulation for determining reflectance relative to an incident angle that was performed on working examples.

FIG. 25B shows the results of a simulation for determining reflectance relative to the thicknesses of gold and silicon dioxide.

FIG. 25C shows the results of a contour plot of reflectance relative to the thicknesses of gold and silicone dioxide.

FIG. 25D shows the results of a simulation for obtaining reflectance relative to the thickness of gold.

FIG. 26 is a diagram for describing the details of the simulation.

FIG. 27 shows the results of a contour plot of reflectance relative to gold and chromium.

### DESCRIPTION OF EMBODIMENTS

Hereinafter, an embodiment according to an aspect of the present invention (also referred to as “this embodiment” hereinafter) will be described with reference to the drawings. However, this embodiment, which will be described below, is merely an example of the present invention in all respects. It goes without saying that various improvements and modifications can be made without departing from the scope of the present invention. In other words, in the implementation of the present invention, the specific configuration corresponding to the embodiment may be employed as appropriate.

### § 1 Configuration Example

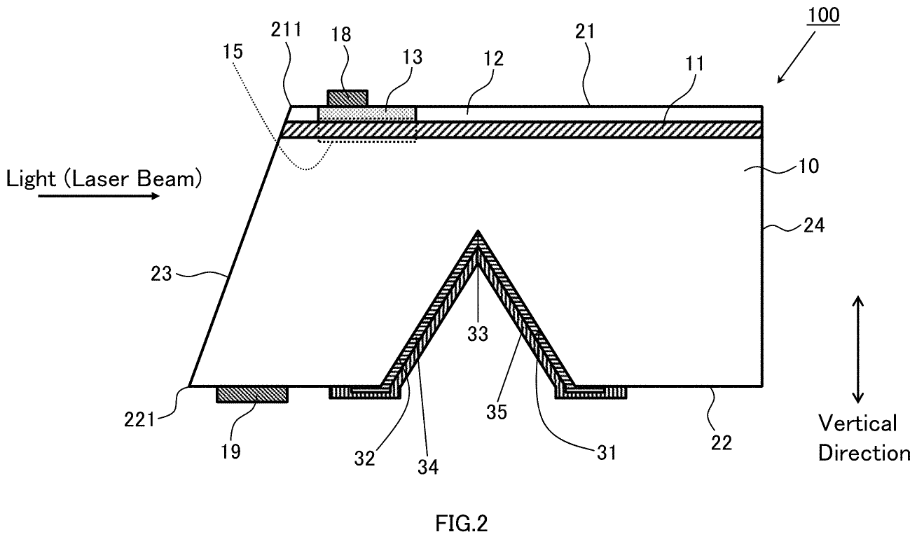

First, the configuration of an end surface incident-type light receiving element 100 according to this embodiment will be described with reference to FIG. 2. FIG. 2 is a schematic cross-sectional view illustrating the end surface incident-type light receiving element 100 according to this embodiment. The end surface incident-type light receiving element 100 according to this embodiment is made of semiconductor materials. The following description illustrates an end surface incident-type light receiving element 100 made of InP (indium phosphide)-based semiconductors.

It should be noted that the directions are defined as follows in this disclosure. A direction in which the crystal of the semiconductor materials grows, that is, the semiconductor materials are layered, is referred to as a “vertical direction” (up-down direction in FIG. 2). A direction that is orthogonal to the vertical direction and in which a light source (semiconductor laser device 90, which will be described later) and the end surface incident-type light receiving element 100 are opposite to each other is referred to as a “front-rear direction” (horizontal direction in FIG. 2). A direction that is orthogonal to the front-rear direction and the vertical direction is referred to as a “width direction” (direction orthogonal to the plane of FIG. 2). FIG. 2 shows a cross section obtained by cutting the end surface incident-type light receiving element 100 in the vertical direction and the front-rear direction.

As shown in FIG. 2, the end surface incident-type light receiving element 100 according to this embodiment includes an n-type InP substrate 10, an active layer 11 formed on a principal surface of the n-type InP substrate 10, and an n-type InP layer 12 formed on the active layer 11. The active layer 11 is made of n-type InGaAs, for example. The active layer 11 and the n-type InP layer 12 are formed using a crystal growth method such as epitaxial growth so as to be layered on the principal surface of the n-type InP substrate 10 in the vertical direction. Zn and the like are diffused in a portion of the n-type InP layer 12, and thus a p-type diffusion region (p-type InP region) 13 is formed. A portion including a PN junction that is formed directly underneath the p-type diffusion region 13 serves as an active region (light receiving portion) 15 that receives light. It should be noted that the active region 15 is an example of a “light receiving region” of the present invention.

The end surface incident-type light receiving element 100 according to this embodiment is formed to have a substantially trapezoidal cross section and includes an upper surface 21 and a lower surface 22 that are opposite to each other in the vertical direction. The upper surface 21 is arranged on the upper side in the vertical direction, and the lower surface 22 is arranged on the lower side in the vertical direction. In this embodiment, the upper surface 21 and the lower surface 22 (excluding a portion in which a groove 31, which will be described later, is to be provided) are formed in a flat shape. It should be noted that a p-type electrode 18 is provided on the p-type diffusion region 13 on the upper surface 21 side, and an n-type electrode 19 is correspondingly provided on the lower surface 22 as appropriate. As the materials of the electrodes (18, 19), Cr/Au, Ti/Pt/Au, or the like may be used for the p-type electrode 18, for example. AuGe/Ni/Au or the like may be used for the n-type electrode 19.

In addition, the end surface incident-type light receiving element 100 includes an end surface 23 arranged on a light source side, the light source emitting light such as a laser beam, and a back surface 24 that is opposite to the end surface 23 in the front-rear direction. The end surface 23 is formed to couple end portions (211, 221) on the light source side of the upper surface 21 and the lower surface 22. The end surface 23 is arranged on the front side, and the back surface 24 is arranged on the rear side. In this embodiment, the end surface 23 and the back surface 24 are formed in a flat shape. It should be noted that the “flat shape” encompasses a perfectly flat state as well as a slightly uneven state due to a manufacturing process such as crystal growth.

In this embodiment, the entire region of the end surface 23 is inclined relative to the vertical direction such that the lower surface 22 side is closer to the light source than the upper surface 21 side is. In other words, the end surface 23 obliquely extends from the lower surface 22 side toward the rear side relative to the vertical direction. Accordingly, as shown in FIG. 2, an angle formed between the end surface 23 and the lower surface 22 (an inclination angle of the end surface 23) is an acute angle. On the other hand, in this embodiment, the back surface 24 is formed extending in the vertical direction. However, the shape of the back surface 24 need not be limited to such an example and may be determined as appropriate in accordance with the embodiment.

Moreover, as shown in FIG. 2, the n-type InP substrate 10 is provided with one groove 31 with a substantially reversed V-shaped cross-section on the lower surface 22 side. The groove 31 is formed through etching or the like, for example, and has a shape extending in the width direction. The groove 31 includes an inclined surface 32 arranged on the end surface 23 side, and an upper end 33 located at a position closest to the upper surface 21. The upper end 33 corresponds to a bottom portion of the groove 31.

The inclined surface 32 obliquely extends from the lower surface 22 side toward the rear side relative to the vertical direction in the same manner as the end surface 23. Accordingly, an angle formed between the inclined surface 32 and the direction in which the lower surface 22 extends (an inclination angle of the inclined surface 32) inside the groove 31 is an acute angle. In other words, an angle formed between the inclined surface 32 and the lower surface 22 is an obtuse angle. The inclined surface 32 is arranged as appropriate so as to reflect light entering through the end surface 23 from the light source. As described later, the light reflected by the inclined surface 32 is received by the active region 15 provided on the upper surface 21 side.

A dielectric film 34 and a metal film 35 are formed on the outer side of each surface of the groove 31 including the inclined surface 32. In this embodiment, as shown in FIG. 2, the dielectric film 34 and the metal film 35 are layered in this order at a region near the groove 31 including the inner walls of the groove 31. However, the range in which the dielectric film 34 and the metal film 35 are formed need not be limited to such an example and may be determined as appropriate in accordance with the embodiment. For example, the dielectric film 34 and the metal film 35 may be formed on only the outer side of the inclined surface 32 of the groove 31.

It should be noted that the respective materials of the dielectric film 34 and the metal film 35 may be selected as appropriate in accordance with the embodiment. As the material of the dielectric film 34, SiO₂ (silicon dioxide), SiN (silicon nitride), TiO₂ (titanium oxide), Al₂O₃ (alumina), or the like may be used, for example. Moreover, as the material of the metal film 35, Au (gold), Cr (chromium), Ti (titanium), Al (aluminum), or the like may be used, for example.

### § 2 Manufacturing Process

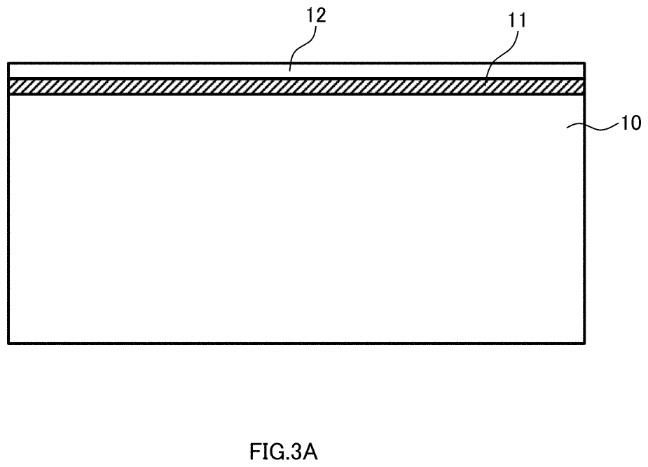

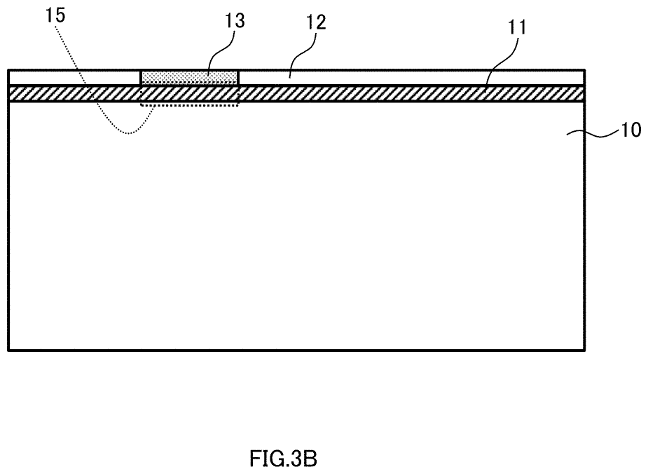

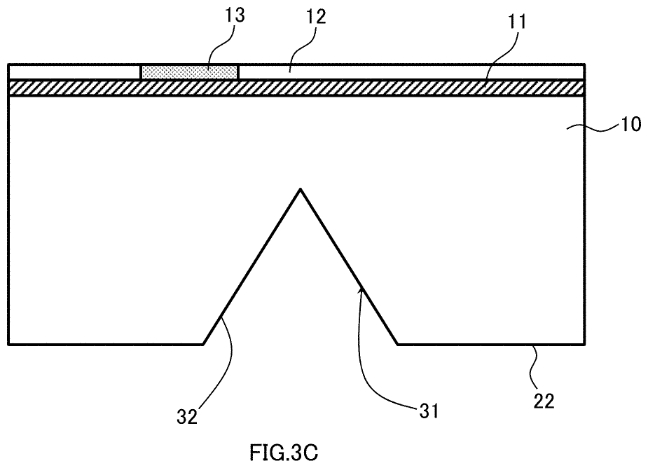

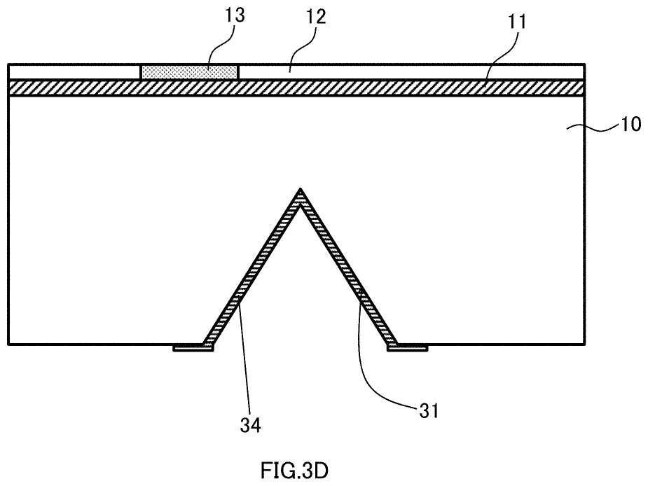

Next, the manufacturing process of the end surface incident-type light receiving element 100 according to this embodiment will be described with reference to FIGS. 3A to 3D. FIGS. 3A to 3D schematically illustrate states in the manufacturing process of the end surface incident-type light receiving element 100 according to this embodiment. It should be noted that the manufacturing process described below is merely an example of a method for manufacturing the end surface incident-type light receiving element 100 according to this embodiment, and the manufacturing steps may be changed as appropriate in accordance with the embodiment.

First, in the first step, the n-type InP substrate 10 to be included in the end surface incident-type light receiving element 100 is prepared as shown in FIG. 3A. Then, the active layer 11 and the n-type InP layer 12 are formed in this order on the principal surface of the n-type InP substrate 10 using a crystal growth method such as epitaxial growth. It should be noted that a buffer layer (not shown) may be formed between the n-type InP substrate 10 and the active layer 11. n-InP is commonly used for buffer layers. The buffer layer serves to mitigate defects and the like that are present on a semiconductor substrate.

In the subsequent second step, p-type impurities such as Zn and Cd (cadmium) are selectively diffused in a portion of the n-type InP layer 12 as shown in FIG. 3B. Thus, the p-type diffusion region 13 is formed in the portion in which the p-type impurities are selectively diffused. A PN junction is formed at the interface between the p-type diffusion region 13 and the active layer 11 by forming the p-type diffusion region 13 as mentioned above, and the active region 15 that receives light and can thus generate a photoelectric current is formed directly underneath the p-type diffusion region 13.

In the subsequent third step, the groove 31 is formed in the lower surface 22 through etching or the like. An anisotropic etching solution such as a bromomethanol mixed solution can be used to form the groove 31, for example. As described later, the inclined surface 32 of the groove 31 located on the end surface 23 side serves as a reflection portion that reflects, toward the active region 15, light entering the n-type InP layer 12.

In the subsequent fourth step, the inner walls of the groove 31 are coated with the dielectric film 34 as shown in FIG. 3D. For example, the dielectric film 34 is formed by layering a dielectric material such as SiO₂, SiN, TiO₂, or Al₂O₃ on the inner walls of the groove 31 using a method such as a plasma CVD method or a thermal CVD method. Furthermore, a portion on which the dielectric film 34 is formed is coated with the metal film 35. For example, the metal film 35 is formed by layering a metal material such as Au, Cr, Ti, or Al on the dielectric film 34 using a method such as vapor deposition or sputtering.

In the subsequent fifth step, the electrodes (18, 19) are formed. The electrodes (18, 19) are formed by layering the above-mentioned electrode materials on the respective portions using a method such as vapor deposition or sputtering.

Furthermore, in the subsequent sixth step, the inclined shape of the end surface 23 is formed using a machining tool such as a dicing wheel. At this time, the end surface 23 with a desired inclination angle can be formed by selecting the tooth angle of the dicing wheel as appropriate. Moreover, the end surface 23 whose entire region is inclined relative to the vertical direction can be formed by completely cutting, from the upper surface 21 to the lower surface 22, a semiconductor construct obtained by performing the manufacturing process from the first step to the fifth step. According to the above-described process, the end surface incident-type light receiving element 100 having the above-mentioned configuration illustrated in FIG. 2 can be manufactured.

### § 3 Operational Example

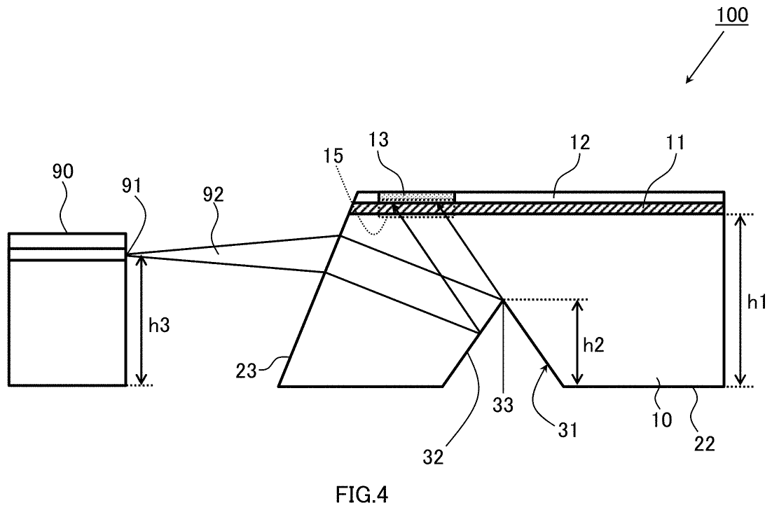

Next, an operational example of the end surface incident-type light receiving element 100 according to this embodiment will be described with reference to FIG. 4. FIG. 4 schematically illustrates a state in which the end surface incident-type light receiving element 100 according to this embodiment receives a laser beam 92. It should be noted that, in FIG. 4, some constituent elements such as the electrodes (18, 19) are not shown, and the end surface incident-type light receiving element 100 is simplified.

As shown in FIG. 4, the end surface incident-type light receiving element 100 is arranged near a semiconductor laser device 90 serving as a light source. At this time, the end surface incident-type light receiving element 100 is arranged such that the end surface 23 faces the semiconductor laser device 90, that is, the semiconductor laser device 90 and the end surface 23 are opposite to each other in the front-rear direction. This enables the laser beam 92 emitted from the semiconductor laser device 90 to be incident on the end surface 23. It should be noted that the semiconductor laser device 90 is appropriately configured to emit the laser beam 92 from a light emitting point 91. A known semiconductor laser device can be used as the semiconductor laser device 90.

The laser beam 92 emitted from the light emitting point 91 of the semiconductor laser device 90 travels in a straight line in the front-rear direction while slightly diffusing in the vertical direction and the width direction, and is incident on the end surface 23 of the end surface incident-type light receiving element 100. Then, the laser beam 92 incident on the end surface 23 enters the n-type InP substrate 10 through the end surface 23. Here, in this embodiment, the end surface 23 is inclined relative to the vertical direction such that the lower surface 22 side is closer to the light source than the upper surface 21 side is. The absolute refractive index of the semiconductor material is larger than the absolute refractive index of air. Accordingly, as shown in FIG. 4, upon entering the n-type InP substrate 10, the laser beam 92 is refracted toward the lower surface 22 provided with the inclined surface 32 serving as a reflection portion, due to the inclination of the end surface 23.

The laser beam 92 that has been refracted toward the lower surface 22 side by the end surface 23 and has entered the n-type InP substrate 10 travels in a straight line in the n-type InP substrate 10 and is incident on the inclined surface 32 of the groove 31. The incident laser beam 92 that has passed through the end surface 23 is reflected toward the upper surface 21 side by the inclined surface 32 in accordance with the law of reflection. In other words, the optical path of the laser beam 92 is bent by the inclined surface 32.

After being reflected by the inclined surface 32, the laser beam 92 reaches the active region 15, and a photoelectric current is generated in the active region 15. The photoelectric current generated in the active region 15 flows through the electrodes (18, 19) and is detected by an external device (not shown) connected to the end surface incident-type light receiving element 100. Accordingly, in the end surface incident-type light receiving element 100, the presence of light (laser beam 92) emitted from the semiconductor laser device 90 can be detected.

### Features

As described above, with this embodiment, the end surface 23 has the above-mentioned inclined shape, thus making it possible to refract the laser beam 92 entering the n-type InP substrate 10 through the end surface 23 toward the lower surface 22 provided with the groove 31. Accordingly, a configuration can be achieved in which the laser beam 92 entering the n-type InP substrate 10 is reflected by the inclined surface 32 of the groove 31 and reaches the active region 15 even if a height h3 to the light emitting point 91 of the light source is larger than a height h2 to the upper end 33 of the groove 31 (i.e., the depth of the groove 31). Therefore, it is possible to suppress a decrease in the photoelectric conversion efficiency (i.e., the sensitivity of the end surface incident-type light receiving element 100) without making the groove 31 deeper in accordance with the height to the light emitting point 91.

For example, in a case where the height h3 to the light emitting point 91 is set to 120 μm, it is possible to prevent a decrease in the photoelectric conversion efficiency even if a height h1 to the active region 15 is set to 150 μm and the height h2 to the upper end 33 of the groove 31 is set to 80 μm. It should be noted that, in this embodiment, the lower surface 22 is used as the basis for the heights h1 to h3 for the sake of ease of description. In other words, the height h1 to the light emitting point 91 corresponds to the length from the lower surface 22 to the light emitting point 91 in the vertical direction. The depth h2 of the groove 31 corresponds to the length from the lower surface 22 to the upper end 33 of the groove 31 in the vertical direction. The height h1 to the active region 15 corresponds to the length from the lower surface 22 to the active region 15 in the vertical direction. In the description below, the lower surface 22 is also used as the basis for heights.

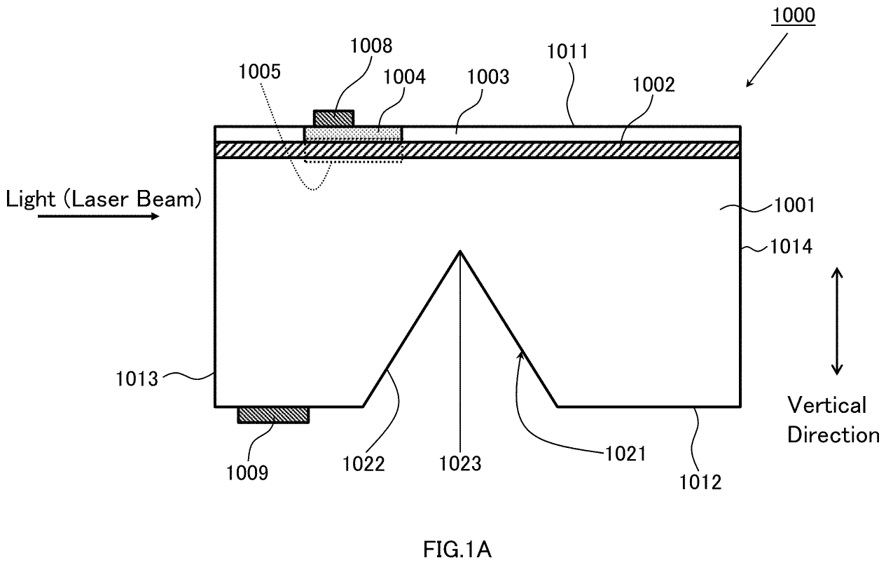

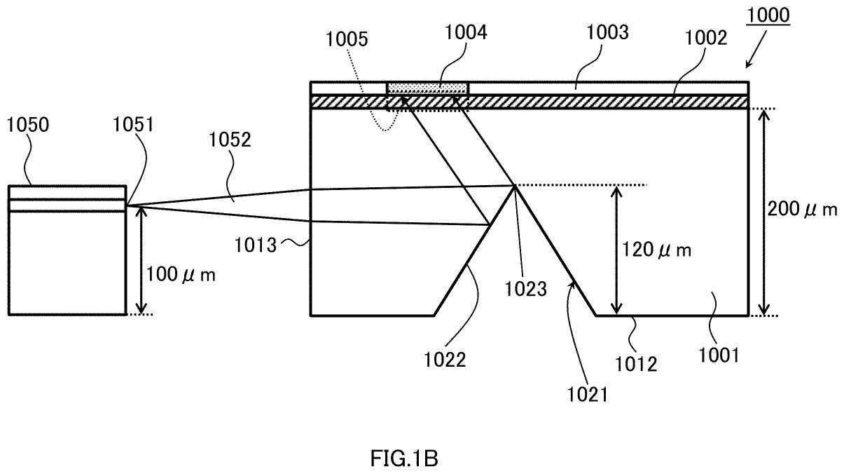

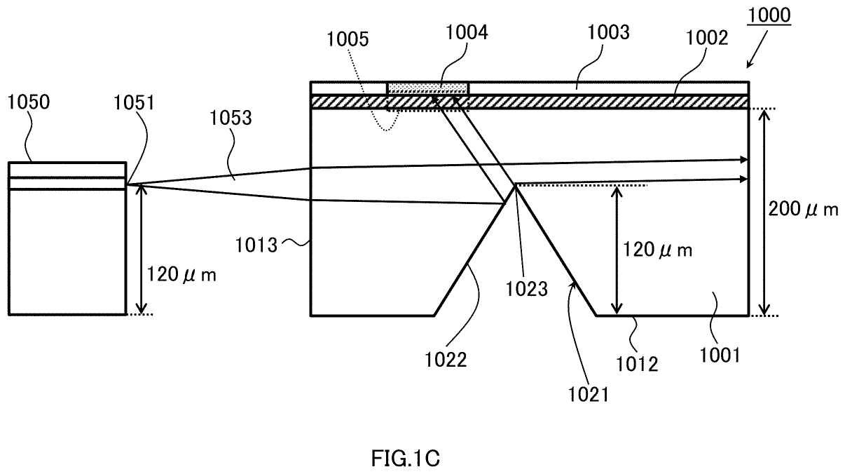

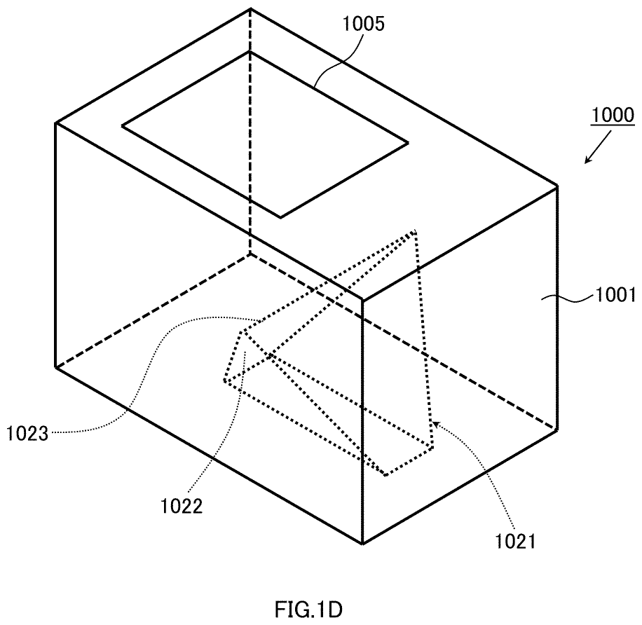

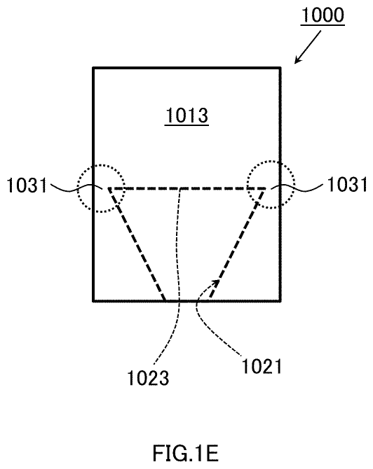

Moreover, with this embodiment, as is clear from the comparison of FIGS. 1B and 1C with FIG. 4, the depth of the groove 31 can be reduced while suppressing a decrease in the photoelectric conversion efficiency. In the above example, it is possible to prevent a decrease in the photoelectric conversion efficiency even if the depth h2 of the groove 31 is reduced by about 40 μm compared with a conventional case. Therefore, it is possible to ensure the mechanical strength of the end surface incident-type light receiving element 100 even if the thickness in the width direction of the end surface incident-type light receiving element 100 is reduced.

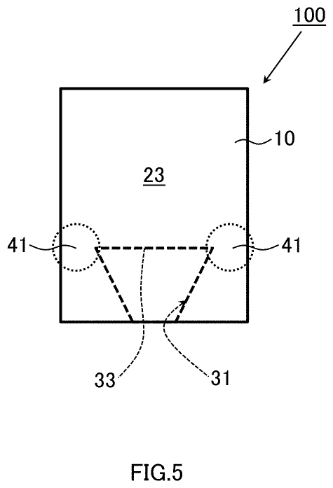

Here, this effect will be described in detail with reference to FIG. 5. FIG. 5 schematically illustrates the end surface incident-type light receiving element 100 according to this embodiment, as viewed from the end surface 23 (light receiving surface) side. As shown in FIG. 5, even when the groove 31 is formed using an anisotropic etching solution in the above-mentioned third step, the depth of the formed groove 31 can be reduced compared with that of the above-mentioned conventional example, thus making it possible to reduce the length in the width direction of the upper end 33 of the groove 31 compared with that of the above-mentioned conventional example. Accordingly, it is possible to prevent the thicknesses of portions 41 located between the respective side walls (surfaces opposite to each other in the width direction) of the n-type InP substrate 10 and the groove 31 from being excessively reduced even when the thickness in the width direction of the end surface incident-type light receiving element 100 is reduced. Therefore, it is possible to reduce the size of the end surface incident-type light receiving element 100 while ensuring the mechanical strength of the end surface incident-type light receiving element 100.

Therefore, with this embodiment, it is possible to suppress a decrease in the photoelectric conversion efficiency without making the groove 31 deeper in accordance with the height to the light emitting point 91. Moreover, since it is possible to reduce the depth of the groove 31 while suppressing a decrease in the photoelectric conversion efficiency, it is possible to ensure the mechanical strength of the end surface incident-type light receiving element 100 even if the thickness in the width direction of the end surface incident-type light receiving element 100 is reduced. Accordingly, with this embodiment, it is possible to provide an end surface incident-type light receiving element that can be reduced in size without impairing the mechanical strength and has improved photoelectric conversion efficiency.

With this embodiment, the inclined shape of the end surface 23 can be formed through a simple cutting step using a machining tool such as a dicing wheel. Accordingly, with this embodiment, it is possible to prevent an excessive increase in the manufacturing cost when manufacturing an end surface incident-type light receiving element having the above-mentioned features.

Moreover, with this embodiment, when the inclined surface 32 of the groove 31 reflects the laser beam 92 in the above-mentioned operation, a portion of the laser beam 92 may pass through the inclined surface 32 depending on the incident angle of the laser beam 92. If a portion of the laser beam 92 passes through the inclined surface 32, the amount of light that reaches the active region 15 decreases correspondingly, and thus the photoelectric conversion efficiency decreases. To address this, with this embodiment, the dielectric film 34 and the metal film 35 are layered on the outer side of the inclined surface 32 (the inner wall of the groove 31). The dielectric film 34 and the metal film 35 can improve the reflectance of the inclined surface 32. Accordingly, it is possible to reduce the likelihood that a portion of the laser beam 92 will pass through the inclined surface 32 and to suppress a decrease in the photoelectric conversion efficiency.

### § 4 Modified Examples

As described above, the embodiment of the present invention has been described, but the foregoing description is merely an example of the present invention in all respects. It goes without saying that various improvements and modifications can be made without departing from the scope of the present invention. For example, the constituent elements of the above-mentioned end surface incident-type light receiving element 100 may be omitted, replaced, and added as appropriate. Also, the shapes and sizes of the constituent elements of the above-mentioned end surface incident-type light receiving element 100 may be determined as appropriate in accordance with the embodiment. For example, the following modifications are possible. It should be noted that, in the following description, constituent elements that are similar to those of the above-mentioned embodiment are denoted by similar reference numerals, and description of configurations that are similar to those of the above-mentioned embodiment is omitted as appropriate. The modified examples below can be combined as appropriate.

4.1

In the above-mentioned embodiment, an InP-based semiconductor is used as the semiconductor material of the end surface incident-type light receiving element 100. However, the semiconductor material of the end surface incident-type light receiving element 100 need not be limited to an InP-based semiconductor and may be selected as appropriate in accordance with the embodiment. For example, it is clear from the description above that semiconductor materials other than InP can be used for the end surface incident-type light receiving element 100 as long as they are transparent to incident light.

4.2

In the above-mentioned embodiment, the dielectric film 34 and the metal film 35 are formed on the outer side of the inclined surface 32. However, the dielectric film 34 and the metal film 35 may also be omitted. Also, a configuration may be employed in which only the dielectric film 34 is omitted, and the outer side of the inclined surface 32, that is, the inner wall of the groove 31, is directly coated with the metal film 35. Moreover, the dielectric film 34 and the metal film 35 may also be formed of different materials so as to include a plurality of layers.

4.3

In the above-mentioned embodiment, the entire region of the end surface 23 is inclined relative to the vertical direction. However, the inclined range of the end surface 23 need not be limited to such an example and may be determined as appropriate in accordance with the embodiment. In other words, it is sufficient that the above-mentioned end surface 23 is formed such that at least a portion is inclined relative to the vertical direction as mentioned above. For example, the end surface 23 may also be formed such that a portion on the upper surface 21 side is inclined relative to the vertical direction and the remainder of the end surface 23 extends in the vertical direction.

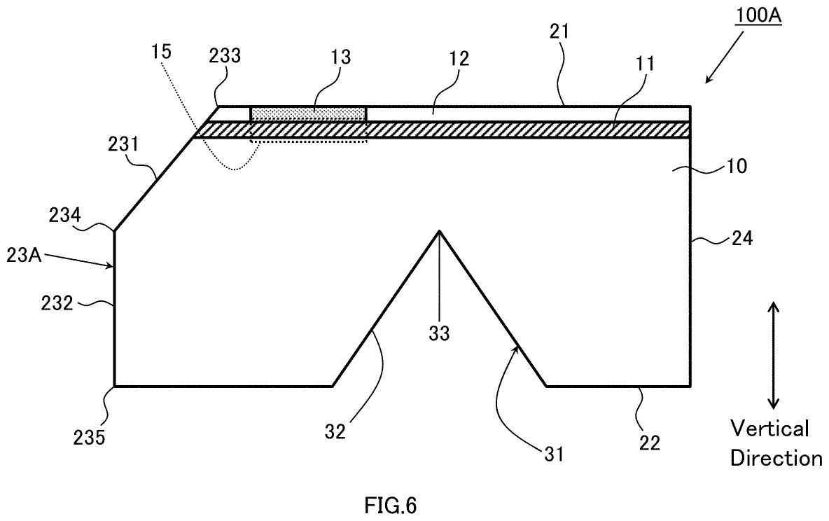

FIG. 6 is a schematic cross-sectional view illustrating an end surface incident-type light receiving element 100A according to this modified example. The end surface incident-type light receiving element 100A according to this modified example is configured in the same manner as the above-mentioned end surface incident-type light receiving element 100, except that the inclined range of an end surface 23A is different from that of the above-mentioned end surface 23. It should be noted that, in FIG. 6, some constituent elements such as the electrodes (18, 19) are not shown, and the end surface incident-type light receiving element 100A is simplified.

In the end surface incident-type light receiving element 100A illustrated in FIG. 6, the end surface 23A is divided into two portions, namely a portion on the upper surface 21 side and a portion on the lower surface 22 side. Specifically, the end surface 23A includes an inclined portion 231 that is inclined relative to the vertical direction, and a vertical portion 232 that is formed extending in the vertical direction. The inclined portion 231 is arranged on the upper surface 21 side and corresponds to the above-mentioned “portion” that is inclined relative to the vertical direction. The vertical portion 232 is arranged on the lower surface 22 side and corresponds to the above-mentioned “remainder” formed extending in the vertical direction.

In this modified example, an upper end 233 of the inclined portion 231 is coupled to an end portion on the end surface 23A side of the upper surface 21. A lower end 234 of the inclined portion 231 is coupled to the upper end of the vertical portion 232. A lower end 235 of the vertical portion 232 is coupled to an end portion on the end surface 23A side of the lower surface 22. This shape of the end surface 23A can be formed by cutting the semiconductor construct from the upper surface 21 side to a desired depth using a dicing wheel and partially breaking the semiconductor construct from this slit in the above-mentioned sixth step.

It should be noted that, in this modified example, a mode in which a portion of the end surface is inclined need not be limited to the example shown in FIGS. 6 to 8. For example, a portion extending in the vertical direction may also be formed between the inclined portion 231 and the end portion of the upper surface 21. The inclined portion 231 may also be constituted by a plurality of portions whose inclination angles are different. An inclined part may also be provided in the vertical portion 232. The arrangement and the inclination angle of the inclined part may be determined as appropriate in accordance with the embodiment.

### Operational Example

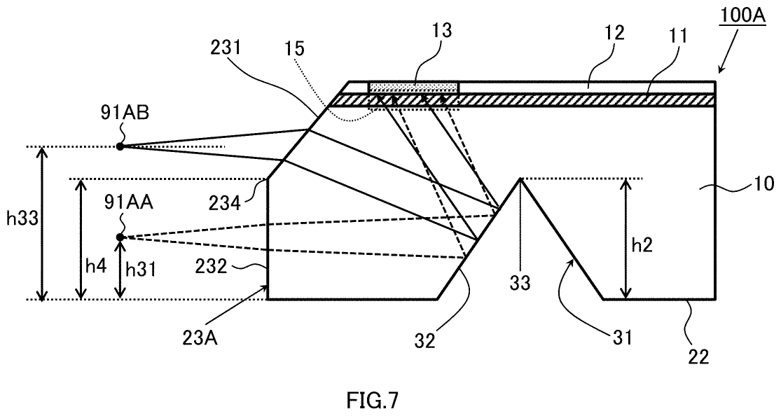

Next, an operational example of the end surface incident-type light receiving element 100A according to this modified example will be described with reference to FIG. 7. FIG. 7 schematically illustrates a state in which the end surface incident-type light receiving element 100A according to this modified example receives a laser beam. In this modified example, the end surface 23A is divided into two portions, namely the inclined portion 231 and the vertical portion 232, and the optical path of light in the n-type InP substrate 10 varies depending on the portion on which the light is incident.

Specifically, when a height h31 to a position at which a light emitting point 91AA of a light source (the above-mentioned semiconductor laser device 90) is arranged is smaller than a height h4 to the lower end 234 of the inclined portion 231 (i.e., the height to the upper end of the vertical portion 232), light emitted from the light emitting point 91AA is incident on the vertical portion 232 of the end surface 23A. In this case, as shown in FIG. 7, although the emitted light is slightly refracted by the vertical portion 232, the light substantially remains traveling in a straight line, is incident on the inclined surface 32 of the groove 31, is reflected by the inclined surface 32, and reaches the active region 15.

On the other hand, when a height h33 to a position at which a light emitting point 91AB of a light source is arranged is larger than the height h4 to the lower end 234 of the inclined portion 231, light emitted from the light emitting point 91AB is incident on the inclined portion 231 of the end surface 23A. In this case, the emitted light is refracted by the inclined portion 231 toward the lower surface 22 provided with the groove 31, is incident on the inclined surface 32 of the groove 31, is reflected by the inclined surface 32, and reaches the active region 15.

### Features

As shown in the above-mentioned conventional example, when the end surface is shaped such that the entire region thereof vertically extends relative the front-rear direction, arranging the light emitting point of the light source at a position higher than the upper end of the groove significantly reduces the photoelectric conversion efficiency of the end surface incident-type light receiving element. To address this, this modification example may also be configured such that the lower end 234 of the inclined portion 231 is located at a position that is as high as the upper end 33 of the groove 31 or is higher than the upper end of the groove. In other words, the height h4 to the lower end 234 of the inclined portion 231 (the height to the upper end of the vertical portion 232) may be equal to or higher than the height h2 to the upper end 33 of the groove 31. This enables light emitted from a light emitting point arranged at a position higher than the upper end of the groove to pass through an inclined part (inclined portion 231) of the end surface of the end surface incident-type light receiving element, to be actively refracted toward the groove side, and be incident on the inclined surface of the groove.

When the entire region of the end surface is inclined relative to the vertical direction as in the above-mentioned embodiment, light emitted from a light emitting point of the light source that is arranged at a position lower than the upper end of the groove is refracted by the end surface toward the lower surface side and may reach the lower surface before it reaches the inclined surface of the groove. In this case, the light emitted from the light source passes through the lower surface and does not reach the active region (light receiving region), and thus the photoelectric conversion efficiency of the end surface incident-type light receiving element may decrease.

To address this, this modified example can be configured such that light emitted from a light emitting point arranged at a position lower than the upper end of the groove is not refracted toward the lower surface side by an inclined part (inclined portion 231), but passes through a vertical part (vertical portion 232) of the end surface of the end surface incident-type light receiving element, and is thus likely to be incident on the inclined surface of the groove. Accordingly, with this modified example, it is possible to provide an end surface incident-type light receiving element that has improved photoelectric conversion efficiency.

### Regarding Total Reflection

Here, depending on the inclination angle of the inclined portion 231 and the inclination angle of the inclined surface 32 of the groove 31, the incident angle of light incident on the inclined surface 32 of the groove 31 via the inclined portion 231 is reduced, and a portion of the light incident on the inclined surface 32 via the inclined portion 231 may pass to the outside. To address this, as mentioned above, forming the dielectric film 34 and the metal film 35 on the outer side of the inclined surface 32 makes it possible to suppress such passing of light. Accordingly, it is preferable to form the dielectric film 34 and the metal film 35 (at least the metal film 35) on the outer side of the inclined surface 32 in order to further improve the sensitivity of the end surface incident-type light receiving element 100A.

In addition to such a method of forming a coating including the metal film 35 on the outer side of the inclined surface 32, a method as described below can be used to suppress the passing of light through the inclined surface 32. That is, even if the dielectric film 34 and the metal film 35 are omitted as described in the above-mentioned modified example 4.2, it is possible to suppress the passing of light through the inclined surface 32 by appropriately determining the inclination angle of the inclined portion 231 and the inclination angle of the inclined surface 32 of the groove 31 such that the light incident on the inclined surface 32 via the inclined portion 231 is fully reflected.

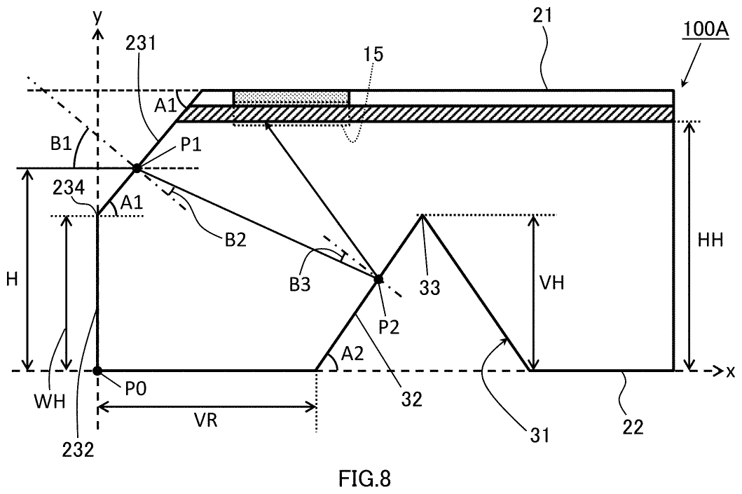

An example of a condition under which light incident on the inclined surface 32 of the groove 31 via the inclined portion 231 of the end surface 23A is fully reflected will be described with reference to FIG. 8. FIG. 8 is a diagram for describing a condition under which light incident on the inclined surface 32 via the inclined portion 231 is fully reflected. The following description describes a condition under which light is fully reflected by the inclined surface 32 when the end surface incident-type light receiving element 100A is arranged near a light source in air and light from the light source is horizontally incident on the inclined portion 231.

It should be noted that, in FIG. 8, the position at which the end portion on the end surface 23A side of the lower surface 22 (i.e., the lower end of the vertical portion 232) is located is shown as a point P0, the position at which light emitted from a light source is incident on the inclined portion 231 is shown as a point P1, and the position at which the light is incident on the inclined surface 32 via the inclined portion 231 is shown as a point P2. In addition, in FIG. 8, the inclination angle of the inclined portion 231 is taken as A1, and the inclination angle of the inclined surface 32 of the groove 31 is taken as A2. Specifically, the inclination angle A1 of the inclined portion 231 is an angle formed between the inclined portion 231 and a direction in which the upper surface 21 and the lower surface 22 extend. The inclination angle A2 of the inclined surface 32 is an angle between the inclined surface 32 and the direction in which the lower surface 22 extends. Furthermore, the incident angle of the light on the inclined portion 231 is taken as B1, the refraction angle of the light on the inclined portion 231 is taken as B2, and the incident angle of the light that has reached the inclined surface 32 via the inclined portion 231 is taken as B3.

Assuming that light travels in a straight line horizontally (in the left-right direction in the diagram), the relationship between the inclination angle A1 of the inclined portion 231 and the incident angle B1 of the light on the inclined portion 231 can be expressed by Formula 2 below. The relationship between the incident angle B1 and the refraction angle B2 can be expressed by Formula 3 below in accordance with Snell's law. Furthermore, the relational expression expressed by Formula 4 below can be obtained by solving the relationship between the angles at the point P2.

$$\begin{matrix}Numerical Formula 2 & \\ A 1 = 90 ° - B 1 & Formula 2 \\ Numerical Formula 2 & \\ \frac{sin B 1}{sin B 2} = \frac{{n}_{2}}{{n}_{1}} & Formula 3 \\ Numerical Formula 4 & \\ B 3 = B 2 + ( A 1 - A 2 ) & Formula 4\end{matrix}$$

In these formulae, n₁ indicates the absolute refractive index of air, and n₂ indicates the absolute refractive index of the semiconductor material of the end surface incident-type light receiving element 100A (n-type InP substrate 10).

For total reflection at the point P2, it is sufficient that the incident angle B3 at the point P2 is larger than the critical angle Bc. The critical angle Bc can be expressed as Formula 5 below in accordance with Snell's law.

$$Numerical Formula 5$$

$$\frac{sin Bc}{1} = \frac{{n}_{1}}{{n}_{2}} \qquad Formula 5$$

The relational expression expressed by Formula 1 can be obtained by solving Formulae 2 to 5 above for A1 and A2. Therefore, setting the inclination angle A1 of the inclined portion 231 and the inclination angle A2 of the inclined surface 32 such that they satisfy Formula 1 above enables light that travels in a straight line, is incident on the inclined portion 231, and reaches the inclined surface 32 via the inclined portion 231 to be fully reflected by the inclined surface 32. This makes it possible to suppress the passing of light through the inclined surface 32.

It should be noted that, if the groove 31 is significantly spaced apart from the end surface 23A, light that has entered the n-type InP substrate 10 through the inclined portion 231 may reach the lower surface 22 before it reaches the inclined surface 32 of the groove 31. Therefore, in the following description, a condition under which light that has entered the n-type InP substrate 10 through the inclined portion 231 reaches the inclined surface 32 of the groove 31 will be determined.

First, as shown in FIG. 8, the point P0 is taken as the center (0, 0), the left-right direction (front-rear direction) is taken as the x axis direction, and the up-down direction (vertical direction) is taken as the y axis direction. The coordinates of the point P1 are taken as (x₁, y₁), and the coordinates of the point P2 are taken as (x₂, y₂). The height to the lower end of the inclined portion 231 is taken as WH, the height to the light source is taken as H, and the height to the upper end 33 of the groove 31 is taken as VH. In addition, the height to the upper end of the inclined portion 231 that can be located inside the end surface incident-type light receiving element 100A is taken as HH. It should be noted that the upper end of the height HH is set on the upper end portion of the n-type InP substrate 10 in the diagram, but the upper end of the height HH may be the upper surface 21 if light can pass through the active layer 11 and the n-type InP layer 12.

At this time, the inclined portion 231 in the xy plane can be expressed by Formula 6 below. The inclined surface 32 in the xy plane can be expressed by Formula 7 below. Furthermore, the optical path of light between the position at which the light enters the n-type InP substrate 10 through the inclined portion 231 and the position at which the light reaches the inclined surface 32 can be expressed by Formula 8 below.

Numerical Formula 6

y=x·tan A1+WH Formula 6

Numerical Formula 7

y=(x−VR)·tan A2 Formula 7

Numerical Formula 8

y=−(x−x₁)·tan(B1−B2)+H Formula 8

The point P2 is a point of intersection of Formulae 7 and 8. Therefore, Formula 9 below can be derived from Formulae 7 and 8.

$$Numerical Formula 9$$

$${x}_{2} = \frac{VR \cdot tan A 2 + {x}_{1} \cdot tan ( B 1 - B 2 ) + H}{tan A 2 + tan ( B 1 - B 2 )} \qquad Formula 9$$

Here, a condition (also referred to as “first condition” hereinafter) under which light that has passed through the inclined portion 231 is prevented from reaching the lower surface 22 before it reaches the inclined surface 32 of the groove 31 is that the x coordinate value x₂ of the point P2 in the optical path is larger than or equal to VR when the light passes through the close vicinity of the lower end 234 of the inclined portion 231 (when the height H to the light source is equal to WH). Therefore, the first condition can be derived as Formula 10 below by substituting 0 for x₁ and WH for H in Formula 9.

$$Numerical Formula 10$$

$$VR \leq \frac{WH}{tan ( B 1 - B 2 )} \qquad Formula 10$$

In addition, a condition (also referred to as “second condition” hereinafter) under which light that has passed through the inclined portion 231 is prevented from passing over the upper end 33 of the groove 31 is that the y coordinate value y₂ of the point P2 in the optical path is smaller than or equal to VH when the light passes through the close vicinity of the upper end of the inclined portion 231 (when the height H to the light source is equal to HH). At this time, the x coordinate value x₁ of the point P1 is expressed by Formula 11 below based on Formula 6 above. Moreover, the relationship between the x coordinate value x2 and the y coordinate value y2 of the point P2 is expressed by Formula 12 below based on Formula 7. Therefore, the second condition can be derived as Formula 13 below based on Formulae 9, 11, and 12.

Numerical Formula 11

HH=×₁·tan A1+WH Formula 11

Numerical Formula 12

y₂=(x₂−VR)·tan A2 Formula 12

Numerical Formula 13

(1+tan(B1−B2)·cot A2)·VH≥HH−{VR+(WH−HH)·cot A1}·tan(B1−B2) Formula 13

Accordingly, determining the lengths of the portions such that they satisfy the first condition expressed by Formula 10 and the second condition expressed by Formula 13 enables the light that has passed through the inclined portion 231 to reach the inclined surface 32 of the groove 31. Therefore, although it is not necessarily required that the above-mentioned first condition and second condition are satisfied, it is preferable to manufacture the above-mentioned end surface incident-type light receiving element 100A such that the first condition and second condition are satisfied.

4.4

In the above-mentioned embodiment and the modified example shown in FIG. 6, portions of the end surfaces that are inclined relative to the vertical direction (the entire region of the end surface 23 and the inclined portion 231) are formed in a flat shape. However, the shapes of these inclined portions need not be limited to such examples and may be determined as appropriate in accordance with the embodiment. For example, these inclined portions may also be formed in a curved shape such that incident light emitted from a light source is condensed on the inclined surface (the above-mentioned inclined surface 32) on the end surface side of the groove.

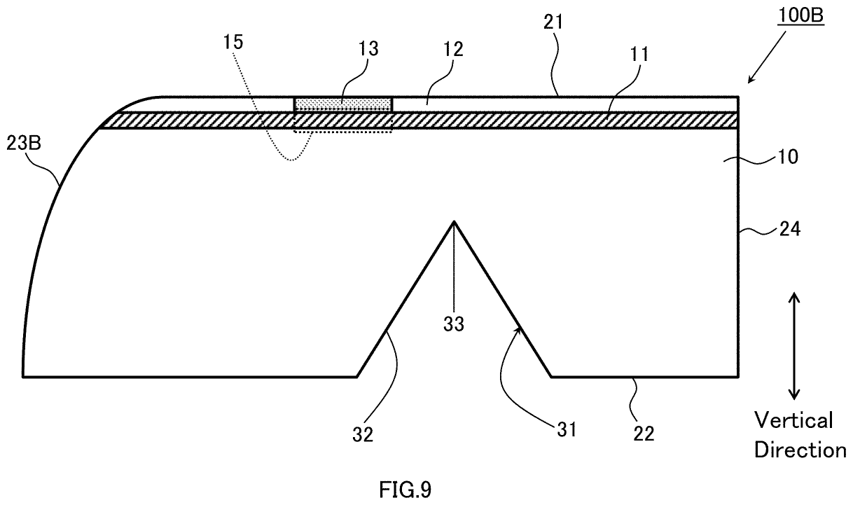

FIG. 9 is a schematic cross-sectional view illustrating an end surface incident-type light receiving element 100B according to this modified example. The end surface incident-type light receiving element 100B according to this modified example is configured in the same manner as the above-mentioned end surface incident-type light receiving element 100, except that the shape of an end surface 23B is different from that of the above-mentioned end surface 23. It should be noted that, in FIG. 9, some constituent elements such as the electrodes (18, 19) are not shown, and the end surface incident-type light receiving element 100B is simplified, as in FIG. 6 above.

In the end surface incident-type light receiving element 100B illustrated in FIG. 9, the entire region of an end surface 23B is formed in a curved shape such that the end surface 23B serves as a lens to condense incident light emitted from a light source on the inclined surface 32 of the groove 31. Specifically, the end surface 23B is formed to have a curved cross section such that the cross section (a plane defined in the front-rear direction and the vertical direction) shown in FIG. 9 has a predetermined curvature radius. The curvature radius of the end surface 23B may be determined as appropriate in accordance with the embodiment.

It should be noted that the region formed in a curved shape need not be limited to such an example. For example, a portion of the end surface 23B may have the same shape as that of at least one of the inclined portion 231 and the vertical portion 232 of the above-mentioned modified example. The end surface 23B may also be constituted by a plurality of portions whose curvature radii are different.

### Operational Example

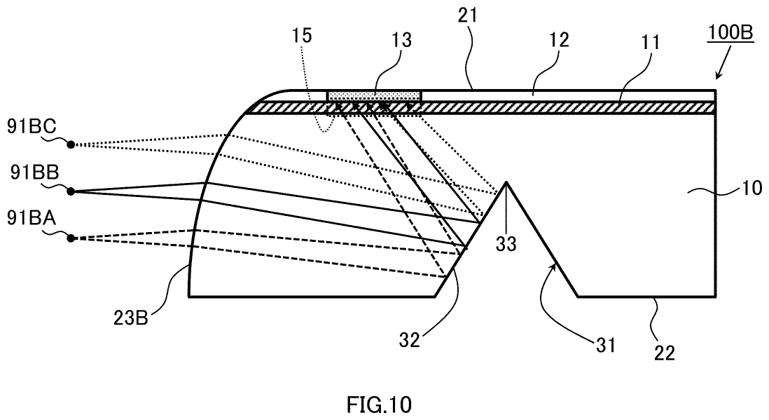

Next, an operational example of the end surface incident-type light receiving element 100B according to this modified example will be described with reference to FIG. 10. FIG. 10 schematically illustrates a state in which the end surface incident-type light receiving element 100B according to this modified example receives a laser beam. In FIG. 10, a light emitting point 91BA is located at the lowest position, a light emitting point 91BB is located at a position higher than the light emitting point 91BA, and the light emitting point 91BC is located at a position higher than the light emitting point 91BB.

In this modified example, the end surface 23B is curved at a constant curvature radius, and therefore, a region on the upper surface 21 side of the end surface 23B is more sharply curved than a region on the lower surface 22 side. Therefore, light entering the n-type InP substrate 10 through a region located on the upper surface 21 side is more sharply refracted toward the lower surface 22 side than light entering through a region located on the lower surface 22 side. In other words, as the height to the light source increases in the order of the light emitting point 91BA, the light emitting point 91BB, and the light emitting point 91BC, light emitted from the light source is more sharply refracted toward the lower surface 22 side by the end surface 23B.

With this configuration, in the same manner as in the above-mentioned end surface incident-type light receiving element 100A, light emitted from a light source located at a low position is not significantly refracted toward the lower surface 22 side, is prevented from reaching the lower surface 22 before it reaches the inclined surface 32 of the groove 31, and can thus be made more likely to be incident on the inclined surface 32. Also, light emitted from a light source located at a high position is significantly refracted toward the lower surface 22 side, is prevented from passing over the upper end 33 of the groove 31, and can thus be made more likely to be incident on the inclined surface 32. Therefore, with this modified example, it is possible to provide an end surface incident-type light receiving element that has improved photoelectric conversion efficiency.

### Manufacturing Process

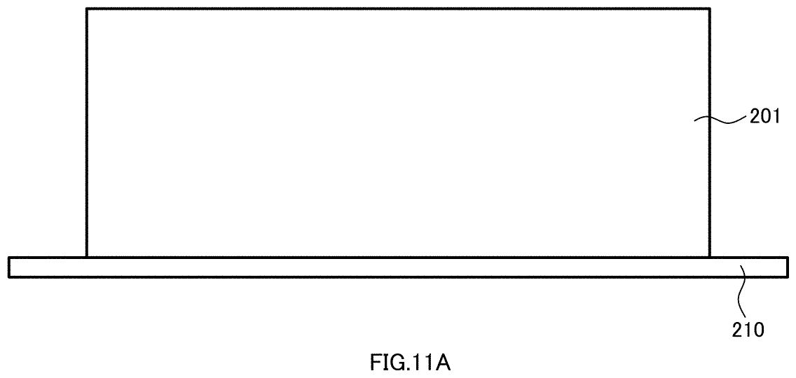

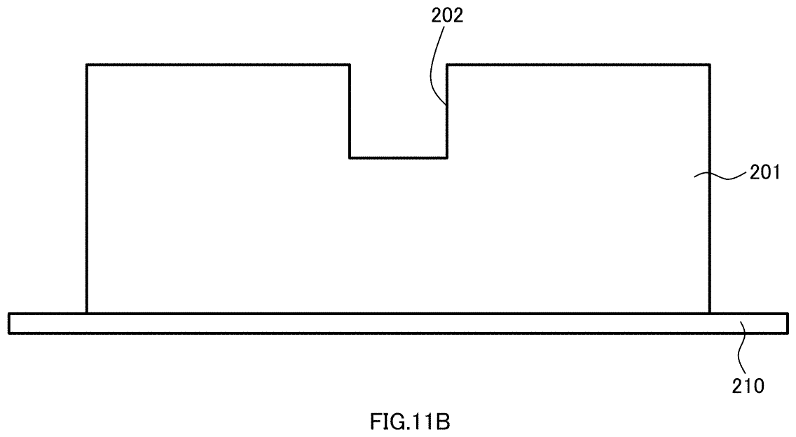

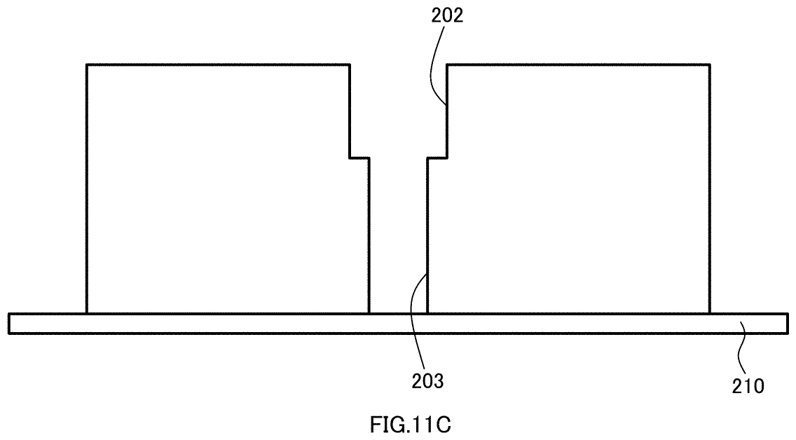

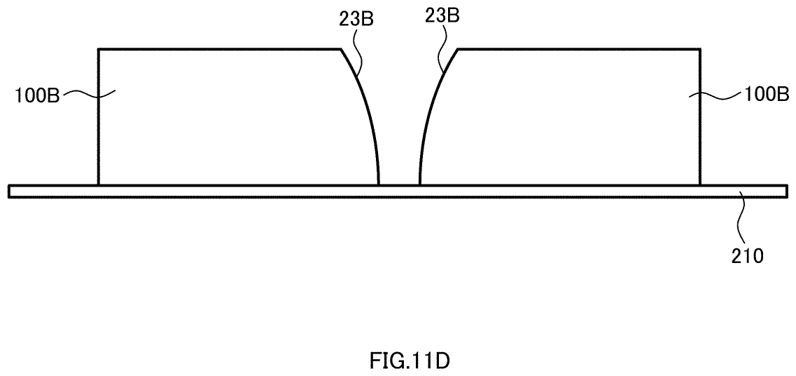

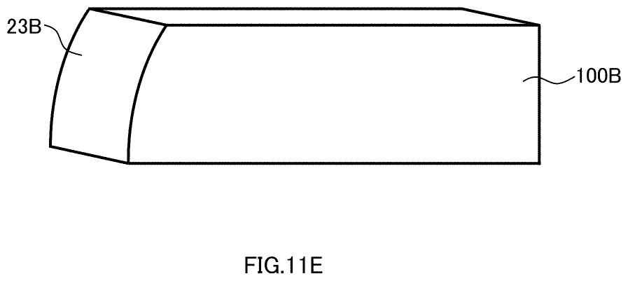

Next, a method for forming the shape of the end surface 23B of the end surface incident-type light receiving element 100B will be described with reference to FIGS. 11A and 11E. The end surface incident-type light receiving element 100B according to this modified example can be manufactured by performing the first step to the fifth step of the manufacturing process according to the above-mentioned embodiment and changing the above-mentioned sixth step as described below.

First, as shown in FIG. 11A, a semiconductor structure 201 that includes the n-type InP substrate 10, the active layer 11, and the n-type InP layer 12, and is provided with a groove 31 is produced by performing the above-mentioned first step to fifth step. Then, the produced semiconductor structure 201 is attached to a substrate 210. It should be noted that, in FIGS. 11A to 11E, the constituent elements such as the n-type InP substrate 10 are not shown.

Next, as shown in FIG. 11B, a groove 202 with an appropriate depth is formed in the semiconductor structure 201 using a machining tool such as a dicing wheel provided with teeth having a relatively large thickness. Subsequently, as shown in FIG. 11C, an additional groove 203 is formed from the bottom portion of the groove 202 using a machining tool provided with teeth having a smaller thickness than the teeth of the machining tool used to form the groove 202. Although the example shown in FIG. 11C is provided with a two-step groove (constituted by the grooves 202 and 203), the number of steps in the groove may be increased in accordance with the embodiment.

Next, chemical etching is performed on the inner walls of the grooves (202, 203) using HBr (hydrogen bromide), H3PO4 (phosphoric acid), or the like. The corner portions of the inner walls are sooner removed than the other portions through chemical etching. Therefore, the inner walls of the multiple-step groove formed using the machining tools are made smoother as shown in FIG. 11D, and are made into the end surfaces 23B with a predetermined curvature radius. The end surface incident-type light receiving element 100B having the above-mentioned curved end surface 23B can thus be produced (in the diagram, two end surface incident-type light receiving elements 100B are produced). Lastly, as shown in FIG. 11E, the end surface incident-type light receiving element 100B is removed from the substrate 210, and thus the final product can be obtained.

4.5

In the above-mentioned embodiment and modified examples, the end surface incident-type light receiving element (100, 100A, 100B) is provided with a single groove 31. However, the number of grooves provided in the end surface incident-type light receiving element need not be limited to one, and a plurality of grooves may also be provided.

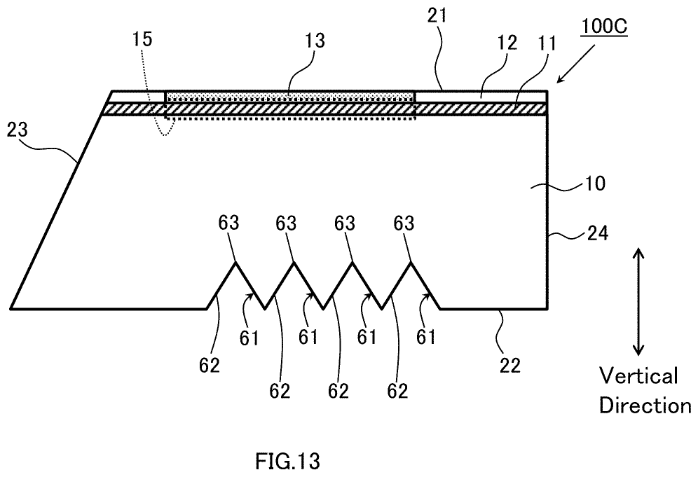

FIG. 13 is a schematic cross-sectional view illustrating an end surface incident-type light receiving element 100C according to this modified example. The end surface incident-type light receiving element 100C according to this modified example is configured in the same manner as the above-mentioned end surface incident-type light receiving element 100, except that the number of the grooves is different. It should be noted that, in FIG. 13, some constituent elements such as the electrodes (18, 19) are not shown, and the end surface incident-type light receiving element 100C is simplified, as in FIG. 6 above etc.

The lower surface 22 of the end surface incident-type light receiving element 1000 illustrated in FIG. 13 is provided with a plurality of grooves 61. The grooves 61 extend in the width direction and are arranged in a light-incident direction (front-rear direction). As with the above-mentioned groove 31, each of the grooves 61 includes an inclined surface 62 arranged on the end surface 23 side, and an upper end 63 located at a position closest to the upper surface 21. The upper end 63 corresponds to the bottom portion of the groove 61.

It should be noted that, although the number of grooves 61 is four in FIG. 13, the number need not be limited to such an example, and two, three, or five or more grooves may be provided. In FIG. 13, the upper ends 63 of the grooves 61 are located at the same height, that is, the grooves 61 have the same depth. Furthermore, the inclined surfaces 62 of the grooves 61 are inclined at the same inclination angle. However, the shapes of the grooves 61 need not be limited to such an example. At least one of the grooves 61 may differ from the others in depth. For example, a configuration may also be employed in which the depths of the grooves 61, that is, the heights to the upper ends 63 of the grooves 61, increase from a groove 61 on the front side toward a groove 61 on the rear side. Moreover, the inclined surface 62 of at least one of the grooves 61 may differ from those of the others in the inclination angle.

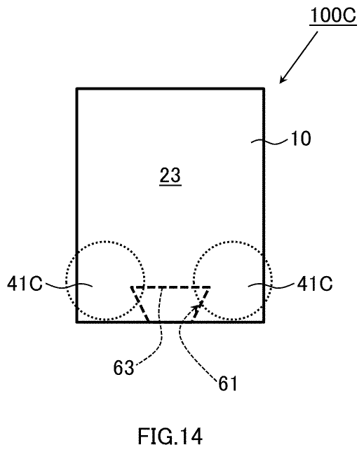

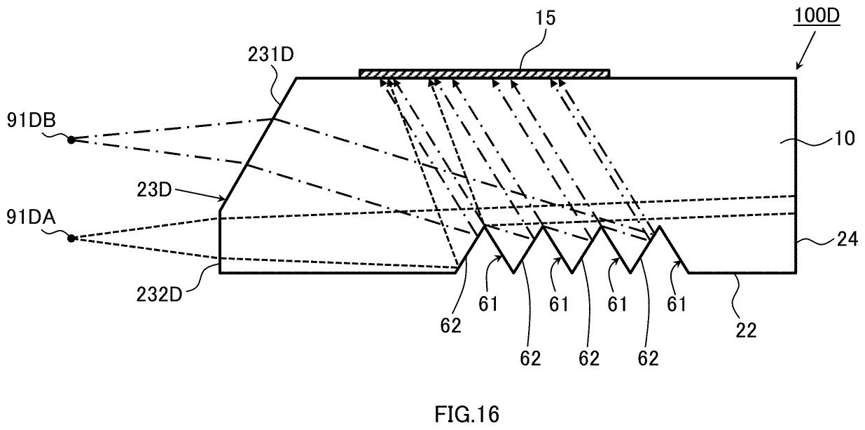

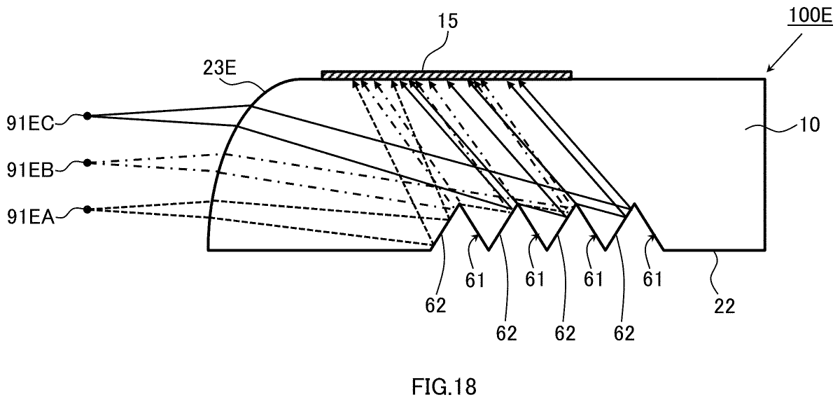

FIG. 14 schematically illustrates the end surface incident-type light receiving element 1000 according to this modified example, as viewed from the end surface 23 side. In this modified example, in the same manner as in the above-mentioned embodiment, the end surface 23 is inclined such that the lower surface 22 side is closer to the light source than the upper surface 21 side is. Accordingly, light emitted from the light source is refracted by the end surface 23 toward the lower surface 22 side and enters the end surface incident-type light receiving element 1000. Therefore, even if the light traveling inside the end surface incident-type light receiving element 100C passes over the upper end 63 of a groove 61 located on the front side, the light may reach the inclined surface 62 of a groove 61 located on the rear side relative to the above-mentioned groove 61 (see FIGS. 16 and 18, which will be described later).

Accordingly, even if the depths of the grooves 61 are smaller than the depth of the above-mentioned groove 31, the inclined surface 62 of any one of the grooves 61 can reflect light emitted from a light source located at a relatively high position. Therefore, with this modified example, it is possible to reduce the depths of the grooves 61 compared with the case where a single groove 31 is provided, while suppressing a decrease in the photoelectric conversion efficiency.

Therefore, as shown in FIG. 14, the thicknesses of portions 41C located between the upper end 63 of each groove 61 and the respective side walls of the n-type InP substrate 10 can be relatively increased. Accordingly, with this modified example, it is possible to improve the mechanical strength of the end surface incident-type light receiving element.

In addition, it is possible to prevent the thicknesses of the portions 41C from being excessively reduced even when the thickness in the width direction of the end surface incident-type light receiving element 1000 is reduced. Therefore, it is possible to reduce the size of the end surface incident-type light receiving element while ensuring the mechanical strength of the end surface incident-type light receiving element.

### Other Configurations

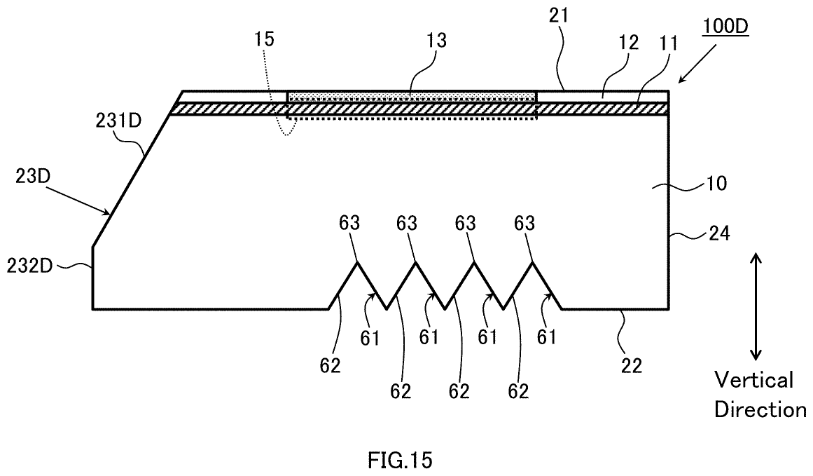

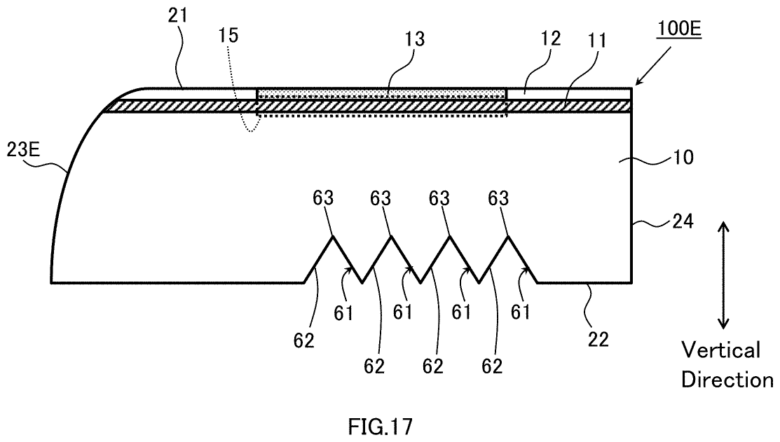

It should be noted that, as shown in FIGS. 15 to 18, the lower surfaces 22 of the end surface incident-type light receiving elements (1A, 1B) according to the above-mentioned modified examples can also be provided with a plurality of grooves 61 instead of a single groove 31. FIGS. 15 and 17 are schematic cross-sectional views illustrating end surface incident-type light receiving elements (100D, 100E) according to modified examples, respectively. FIGS. 16 and 18 schematically illustrate states in which the end surface incident-type light receiving elements (100D, 100E) according to the modified examples receive a laser beam, respectively. It should be noted that, in the diagrams, some constituent elements such as the electrodes (18, 19) are not shown, and the end surface incident-type light receiving elements (100D, 100E) are simplified, as in FIG. 6 above.

The end surface incident-type light receiving element 100D illustrated in FIGS. 15 and 16 is configured in the same manner as the above-mentioned end surface incident-type light receiving element 100A, except that a plurality of grooves 61 are provided instead of a single groove 31. An inclined portion 231D and a vertical portion 232D of an end surface 23D correspond to the inclined portion 231 and the vertical portion 232 of the above-mentioned end surface 23A, respectively.

In FIG. 16, a light emitting point 91DA is arranged such that light emitted therefrom is incident on the vertical portion 232D, and a light emitting point 91DB is arranged such that light emitted therefrom is incident on the inclined portion 231D. The end surface incident-type light receiving element 100D according to this modified example operates as described below.

That is, although light emitted from the light emitting point 91DA is slightly refracted by the vertical portion 232, the light substantially remains traveling in a straight line and is incident on the inclined surface 62 of a groove 61 arranged closest to the end surface 23D. Then, the light is reflected by the inclined surface 62 and reaches the active region 15. If the grooves 61 have the same depth, and a portion of the light entering through the vertical portion 232D passes over the upper end 63 of the groove 61 arranged closest to the end surface 23D, there is a possibility that a portion of the light will not be reflected by the inclined surfaces 62 of the grooves 61 and pass through the back surface 24 as shown in FIG. 16.

On the other hand, light emitted from the light emitting point 91DB is refracted by the inclined portion 231 toward the lower surface 22 side, and therefore, even if light passes over the upper end 63 of a groove 61 located on the front side, the light may reach the inclined surface 62 of a groove 61 located on the rear side relative to the above-mentioned groove 61. Accordingly, the light emitted from the light emitting point 91DB can be reflected by the inclined surface 62 of at least one of the grooves 61. As an example, FIG. 16 shows a state in which light emitted from the light emitting point 91DB is reflected by the inclined surfaces 62 of four grooves 61.

The end surface incident-type light receiving element 100E illustrated in FIGS. 17 and 18 is configured in the same manner as the above-mentioned end surface incident-type light receiving element 100B, except that a plurality of grooves 61 are provided instead of a single groove 31. An end surface 23E corresponds to the above-mentioned end surface 23B.

In FIG. 18, a light emitting point 91EA is located at the lowest position, a light emitting point 91EB is located at a position higher than the light emitting point 91EA, and the light emitting point 91EC is located at a position higher than the light emitting point 91EB. The end surface incident-type light receiving element 100E according to this modified example operates as described below.

That is, in the same manner as in the above-mentioned end surface incident-type light receiving element 100B, light entering the n-type InP substrate 10 through a region located on the upper surface 21 side is more sharply refracted by an end surface 23B of the end surface incident-type light receiving element 100E toward the lower surface 22 side than light entering through a region located on the lower surface 22 side. In other words, as the height to the light source increases in the order of the light emitting point 91EA, the light emitting point 91EB, and the light emitting point 91EC, light emitted from the light source is more sharply refracted toward the lower surface 22 side by the end surface 23E.

At this time, even if the light passes over the upper end 63 of a groove 61 located on the front side, the light may reach the inclined surface 62 of a groove 61 located on the rear side relative to the above-mentioned groove 61. Accordingly, the light emitted from the light emitting points (91EA, 91EB, 91EC) can be reflected by the inclined surface 62 of at least one of the grooves 61. It should be noted that, in the case of this modified example, the end surface 23E need only be formed to condense light emitted from a light source on at least one of the inclined surfaces 62 of the grooves 61.

### Working Examples

Hereinafter, examples of the present invention will be described. However, the present invention is not limited to these examples. In order to examine the performance of the end surface incident-type light receiving element of the present invention, the following simulations were performed. The simulations will be described below.

### (1) First Simulation

In a first simulation, regarding modes provided with a single groove (the end surface incident-type light receiving elements 100 to 100B), the relationship between the height to the light emitting point of a light source and the photoelectric conversion efficiency (sensitivity) was examined.

An end surface incident-type light receiving element according to a first working example had the same configuration as that of the above-mentioned end surface incident-type light receiving element 100, and the parameters for the constituent elements were as follows.

### Properties of First Working Example

Inclination angle of end surface: 65 degrees
Inclination angle of inclined surface: 54.7 degrees
Depth of groove: 80 μm
Height of end surface incident-type light receiving element: 150 μm
Length between end portion on end surface side of lower surface and end portion of groove (lower end of inclined surface): 140 μm

An end surface incident-type light receiving element according to a second working example had the same configuration as that of the above-mentioned end surface incident-type light receiving element 100A, and the parameters for the constituent elements were as follows.

### Properties of Second Working Example

Inclination angle of end surface: 60 degrees
Inclination angle of inclined surface: 54.7 degrees
Height to lower end of inclination portion: 80 μm
Depth of groove: 80 μm
Height of end surface incident-type light receiving element: 150 μm
Length between end portion on end surface side of lower surface and end portion of groove (lower end of inclined surface): 140 μm

An end surface incident-type light receiving element according to a third working example had the same configuration as that of the above-mentioned end surface incident-type light receiving element 100B, and the parameters for the constituent elements were as follows.

### Properties of Third Working Example

Curvature radius of end surface: 300 μm
Inclination angle of inclined surface: 54.7 degrees
Depth of groove: 80 μm
Height of end surface incident-type light receiving element: 150 μm
Length between end portion on end surface side of lower surface and end portion of groove (lower end of inclined surface): 140 μm

On the other hand, an end surface incident-type light receiving element according to a comparative example had the same configuration as that of the end surface incident-type light receiving element 1000 according to the conventional example, and the parameters for the constituent elements were as follows.

### Properties of Comparative Example

Inclination angle of inclined surface: 54.7 degrees
Depth of groove: 120 μm

Height of end surface incident-type light receiving element: 200 μm
Length between end portion on end surface side of lower surface and end portion of groove (lower end of inclined surface): 140 μm

The absolute refractive index of the semiconductor material of the end surface incident-type light receiving element of the working examples and comparative example was set to 3.224, and the absolute refractive index of air was set to 1.0. A light source was configured such that the spread angle of a laser beam was set to 14 degrees, and a light emitting point was arranged at a position spaced apart by 100 μm from the end surface incident-type light receiving elements.

Under the above-described conditions, the efficiencies of photoelectric conversion (coupling efficiencies) of the working examples and comparative example were determined by calculating how much light emitted from the light emitting point was reflected by the groove and reached the active region while increasing the height to the light emitting point by 5 μm from 0 μm to 140 μm. In other words, the ratio of light that reached the active region was determined as a coupling efficiency.

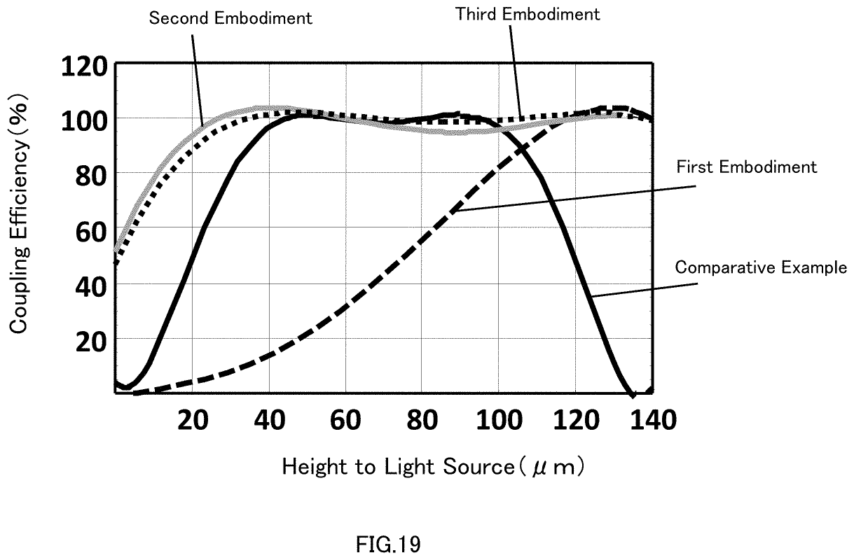

FIG. 19 shows the calculation results of the first simulation. As shown in FIG. 19, the coupling efficiency of the first working example was lower than that of the comparative example when the light emitting point was arranged at a height of 100 μm or lower, but the coupling efficiency of the first working example was comprehensively higher than that of the comparative example when the light emitting point was arranged at a height in a range from 100 μm to 120 μm. A height in a range from 100 μm to 120 μm is a height at which the light emitting point is arranged during normal use. In addition, the depth of the groove of the first working example is 40 μm smaller than the depth of the groove of the comparative example. Accordingly, it was found that, with the above-mentioned embodiment, an end surface incident-type light receiving element that has improved photoelectric conversion efficiency during normal use and can be reduced in size compared with the conventional example can be obtained.

The coupling efficiencies of the second working example and the third working example were similar to or higher than that of the comparative example irrespective of the height to the light source. In particular, it was found that the coupling efficiency of the comparative example sharply decreased when the height to the light source was 40 μm or lower or 100 μm or higher, whereas those of the second working example and the third working example did not decrease very much and high coupling efficiencies were obtained. Therefore, it was found that, with the above-mentioned modified examples, an end surface incident-type light receiving element that has improved photoelectric conversion efficiency can be obtained even in the case where the depth of the groove is smaller compared with the conventional case. Furthermore, it was found from this point that the size can be reduced while ensuring high photoelectric conversion efficiency.

### (2) Second Simulation

In a second simulation, an end surface incident-type light receiving element provided with a plurality of grooves was used as a fourth working example in order to examine the influence of the number of grooves on a coupling efficiency.

Specifically, the end surface incident-type light receiving element according to the fourth working example had the same configuration as that of the above-mentioned end surface incident-type light receiving element 100E, and the parameters for the constituent elements were as follows.

### Properties of Fourth Working Example

Curvature radius of end surface: 230 μm
Inclination angle of inclined surface: 54.7 degrees
Depth of groove: 30 μm
Height of end surface incident-type light receiving element: 150 μm
Number of grooves: 4
Lengths of grooves in front-rear direction: 42 μm
Length between end portion on end surface side of lower surface and end portion (lower end of inclined surface) of groove located closest to end surface: 140 μm

The conditions for the absolute refractive indices of the semiconductor material and air and the condition for the light source were set to be the same as those in the above-mentioned first simulation. Under these conditions, in the same manner as in the above-mentioned first simulation, the coupling efficiency of the fourth working example was determined by calculating how much light emitted from the light emitting point was reflected by the grooves and reached the active region while increasing the height to the light emitting point by 5 μm from 0 μm to 140 μm.

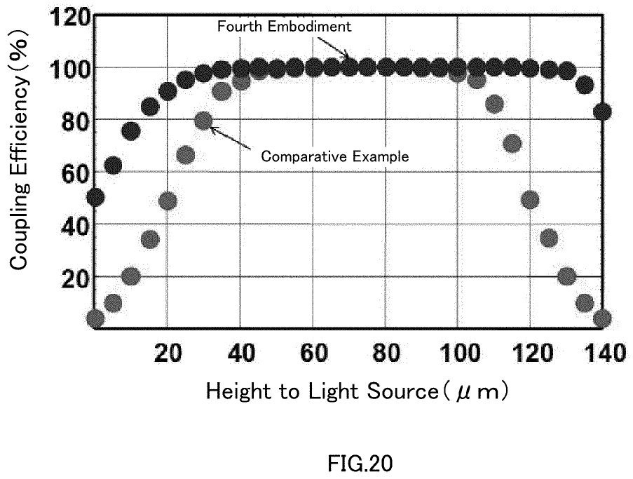

FIG. 20 shows the calculation results of the coupling efficiencies of the fourth working example and the above-mentioned comparative example. As shown in FIG. 20, the coupling efficiency of the fourth working example was similar to or higher than that of the comparative example irrespective of the height to the light source. In particular, it was found that the coupling efficiency of the comparative example sharply decreased when the height to the light source was 40 μm or lower or 100 μm or higher, whereas that of the fourth working example did not decrease very much and a high coupling efficiency was obtained. Therefore, it was found that, by increasing the number of grooves, an end surface incident-type light receiving element that has improved photoelectric conversion efficiency can be obtained even in the case where the depths of the grooves are even smaller compared with the conventional case. Furthermore, it was found from this point that the end surface incident-type light receiving element can be further reduced in size while ensuring high photoelectric conversion efficiency.

Next, in order to examine the influence of the number of grooves on the coupling efficiency when end surfaces have the same shape, the end surface incident-type light receiving element according to the third working example was modified as described below, and thus an end surface incident-type light receiving element according to a fifth working example was further obtained. Only the modified parameter is listed below.

### Properties of Fifth Working Example

Depth of groove: 30 μm

The conditions for the absolute refractive indices of the semiconductor material and air and the condition for the light source were set to be the same as those in the above-mentioned first simulation. Under these conditions, the coupling efficiencies of the fourth working example and the fifth working example were determined by calculating how much light emitted from the light emitting point was reflected by the grooves and reached the active region while setting the height to the light source to 30 μm, 75 μm, and 120 μm and increasing the curvature radii of these working examples by 10 μm from 200 μm to 300 μm.

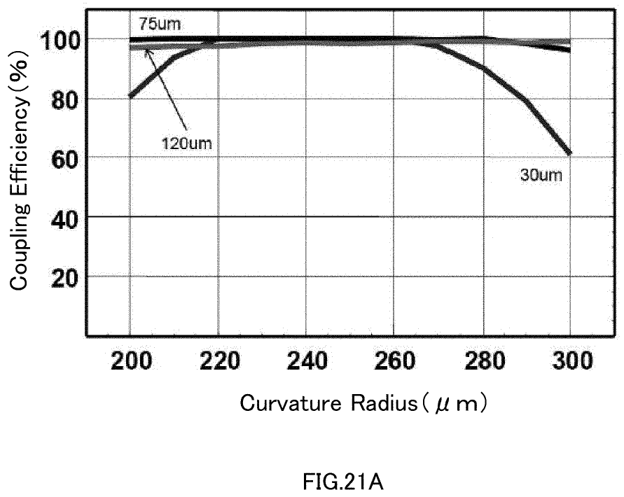

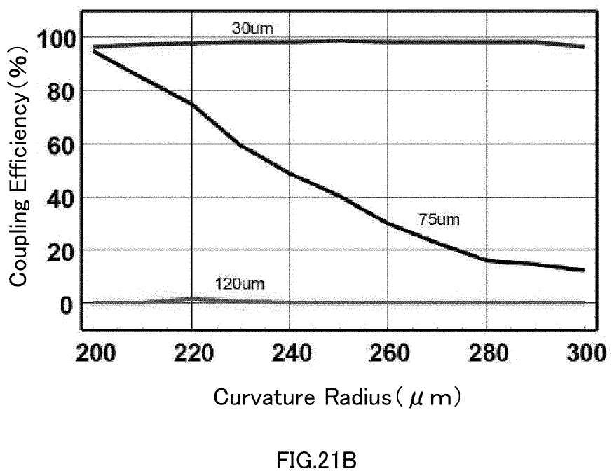

FIG. 21A shows the calculation results from the fourth working example. FIG. 21B shows the calculation results from the fifth working example. It was found that, when the height to the light emitting point was 30 μm, which is the same as the depths of the grooves, the coupling efficiency of the fourth working example slightly decreased in the case where the curvature radius of the end surface was set to 220 μm or less or 260 μm or more. However, it was found that, when the height to the light emitting point was 75 μm or 120 μm, the coupling efficiency of the fourth working example was substantially constant even in the case where the curvature radius of the end surface was set to any value in a range from 200 μm to 300 μm.

On the other hand, it was found that, when the height to the light emitting point was 30 μm, the coupling efficiency of the fifth working example was substantially constant even in the case where the curvature radius of the end surface was set to any value in a range from 200 μm to 300 μm. However, it was found that, when the height to the light emitting point was 75 μm or 120 μm, the coupling efficiency of the fifth working example decreased in the case where the curvature radius was set to 200 μm or more. In particular, it was found that, when the height to the light emitting point was 120 μm, the coupling efficiency was approximately zero even in the case where the curvature radius of the end surface was set to any value in a range from 200 μm to 300 μm.

It was found from the above-described results that, when the depth of the groove was further reduced compared with a conventional case, providing a plurality of grooves in the lower surface was very effective in achieving a high coupling efficiency. In particular, it was found that, in a case where the height to the light source can be larger than the depth of the groove, providing a plurality of grooves in the lower surface makes it possible to achieve a high coupling efficiency even when the curvature radius of the end surface varies.

### (3) Third Simulation

In a third simulation, investigation into which range on the upper surface side is suitable for arrangement of the active region (light receiving portion) was carried out.

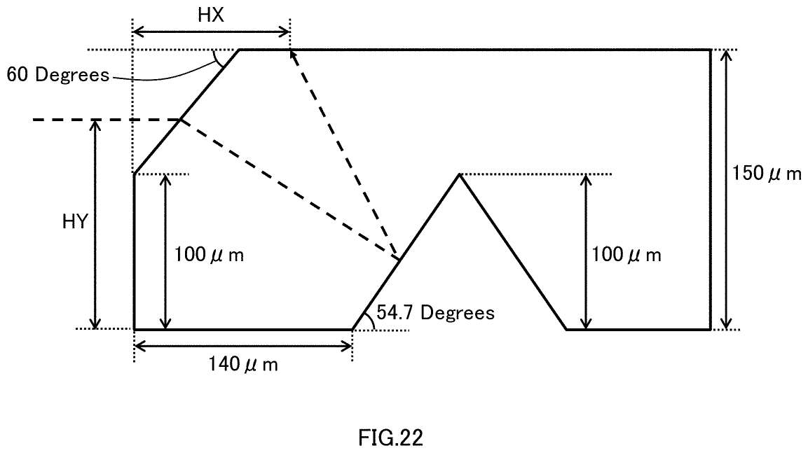

FIG. 22 is a diagram for describing the details of the third simulation. As shown in FIG. 22, an end surface incident-type light receiving element according to a sixth working example obtained by changing the depth of the groove of the above-mentioned second working example to 100 μm and the inclination of the inclined portion thereof to 60 degrees was used in the third simulation. The height to the active region from the lower surface in the sixth example was set to 150 μm. The conditions for the absolute refractive indices of the semiconductor material and air were set to be the same as those in the above-mentioned first simulation. Then, a distance (HX in the diagram) between the end surface (vertical portion) and an arrival position of light that was emitted from a light source and reflected by the inclined surface of the groove, at an active region arrangement height, was calculated while the height HY to the light source was increased as appropriate from 0 μm to 140 μm.

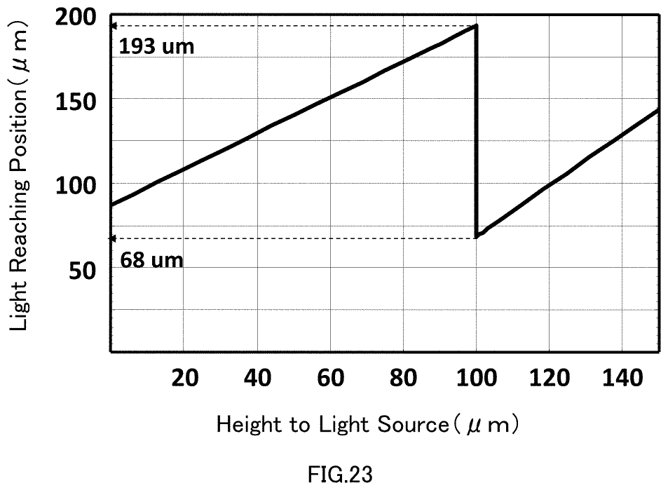

FIG. 23 shows the calculation results. It was found from the calculation results that, in the above-mentioned sixth working example, all of the light reflected by the inclined surface of the groove could be photoelectrically converted by providing the active region in a range between a position that is 68 μm away from the end surface (vertical portion) in the front-rear direction and a position that is 193 μm away from the end surface (vertical portion) in the front-rear direction. As described above, it is possible to prevent arrangement of an active region in a range where light does not reach by calculating a range of an arrival position of light that has been emitted from a light source and reflected by the inclined surface of the groove, at an active region arrangement height. This makes it possible to reduce the manufacturing cost of the end surface incident-type light receiving element.

### (4) Fourth Simulation

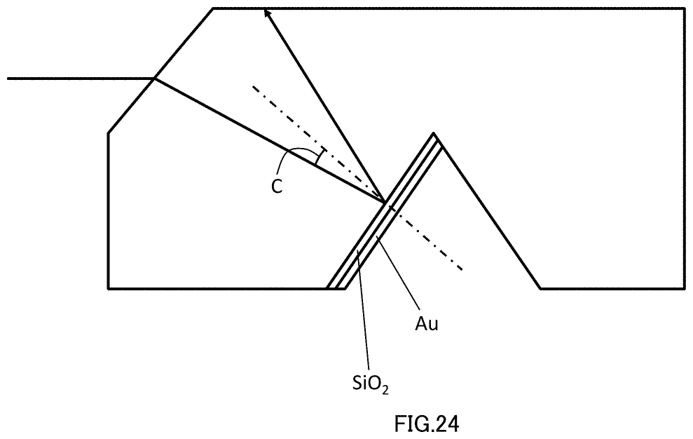

In a fourth simulation, a seventh working example shown in FIG. 24, which will be described below, was used to examine an effect caused by providing a dielectric film and a metal film.

FIG. 24 is a diagram for describing the details of the fourth simulation. As shown in FIG. 24, the end surface incident-type light receiving element according to the seventh working example had the same configuration as that of the above-mentioned end surface incident-type light receiving element 100A, and a dielectric film made of SiO₂ and a metal film made of Au were layered in this order on the outer side of the inclined surface of the groove (inner wall of the groove). The conditions for the absolute refractive indices of the semiconductor material and air were set to be the same as those in the above-mentioned first simulation. The absolute refractive index of the dielectric film (SiO₂) was set to 1.45, and the complex refractive index of the metal film (Au) was set to “0.55−11.5×j”. j indicates an imaginary number.

Under these conditions, the reflectance of the inclined surface was calculated in a first case where a dielectric film with a thickness of 1000 nm and a metal film with a thickness of 1000 nm were provided and a second case where only a dielectric film with a thickness of 1000 nm was provided while a light incident angle C with respect to the inclined surface was changed as appropriate from 0 degrees to 40 degrees. Moreover, in a state in which the incident angle C is set to 14.2 degrees, the reflectance of the inclined surface was calculated while the thicknesses of a dielectric film and a metal film were changed as appropriate.

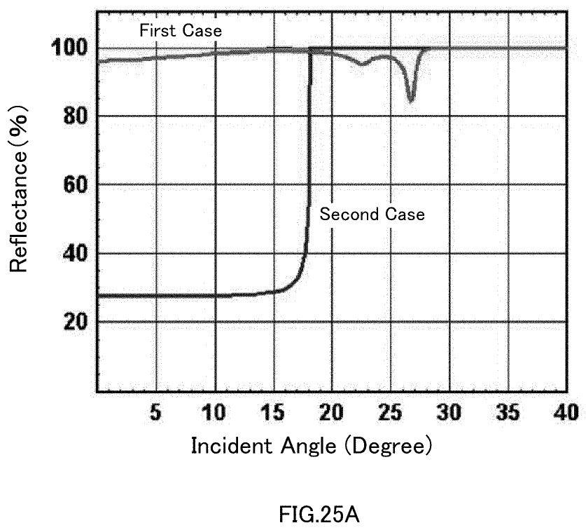

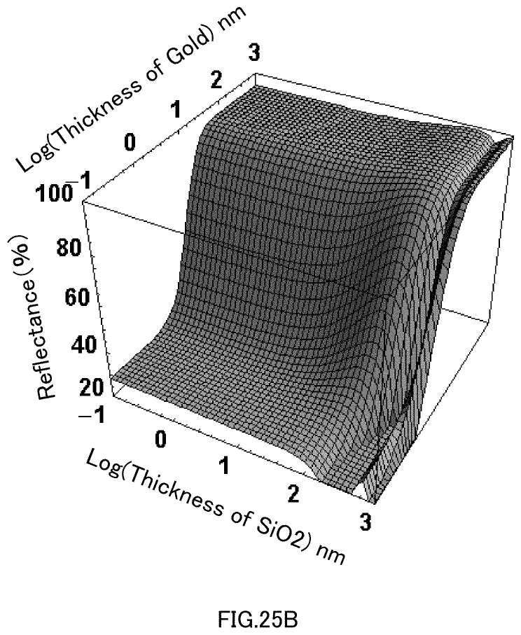

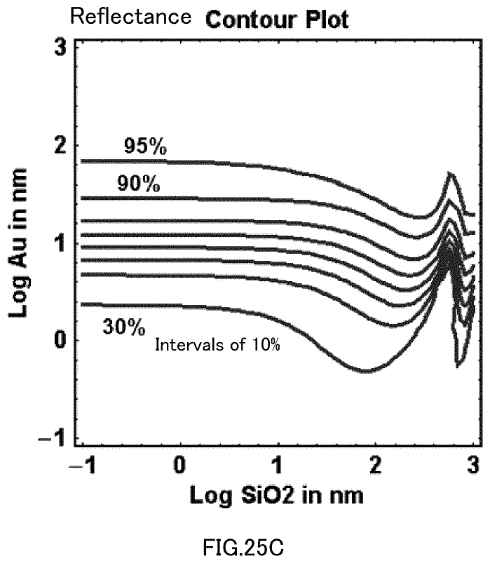

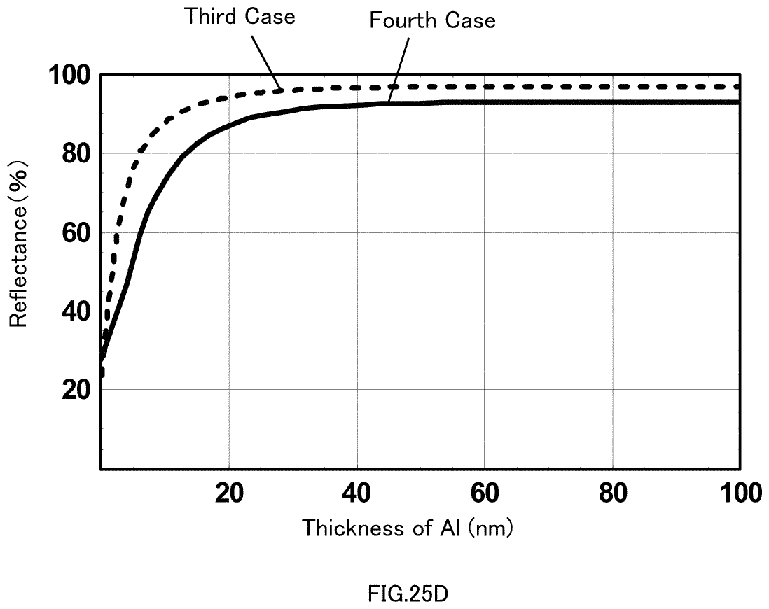

FIG. 25A shows the calculation results of the reflectance of the inclined surface from the first case and the second case, which were determined while changing the incident angle C. FIG. 25B shows the calculation results of the reflectance of the inclined surface relative to the thicknesses of the dielectric film (SiO₂) and the metal film (Au) when the incident angle C was 14.2 degrees. Furthermore, FIG. 25C shows the results of a contour plot of the reflectance relative to the thicknesses of the dielectric film (SiO₂) and the metal film (Au) when the light incident angle C was 14.2 degrees.

It was found from the results shown in FIG. 25A that providing not only a dielectric film but also a metal film made it possible to effectively improve the reflectance of the inclined surface. In particular, it was found that, in a case where the light incident angle C can be 20 degrees or smaller, providing a metal film on the outer side of the inclined surface is effective for improving the coupling efficiency of the end surface incident-type light receiving element.

Also, it was found from the results shown in FIGS. 25B and 25C that, when the metal film (Au) had a thickness of 10 nm or smaller, the reflectance of the inclined surface was 50% or less. Therefore, in order to examine the thickness of the metal film (Au) that is effective for improving the reflectance of the inclined surface, the reflectance of the inclined surface was calculated in a third case where the thickness of the dielectric film (SiO₂) was set to 100 nm in the above-mentioned seventh working example and a fourth case where the thickness of the dielectric film (SiO₂) was set to 10 nm while the thickness of the metal film (Au) was changed as appropriate. It should be noted that the light incident angle C was set to 14.2 degrees as in the cases described above.

FIG. 25D shows the calculation results. It was found from the results shown in FIG. 25D that, in both cases, the reflectance of the inclined surface could be improved to 90% or more by setting the thickness of the metal film (Au) to 40 nm or larger. It was thus found that, when a metal film made of Au is provided on the outer side of the inclined surface, setting the thickness of the metal film to 40 nm or larger makes it possible to effectively improve the reflectance of the inclined surface.

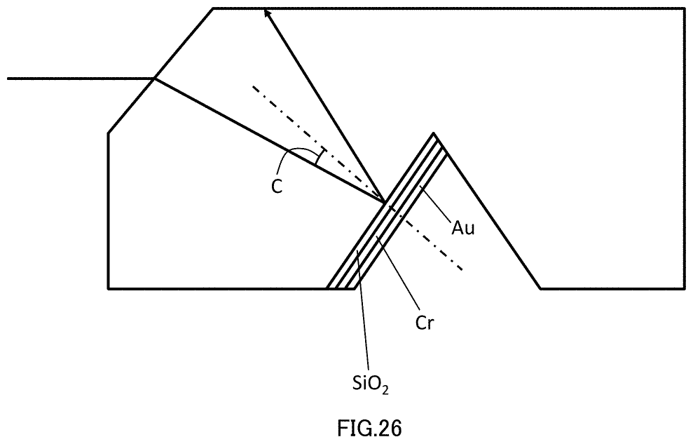

Furthermore, an end surface incident-type light receiving element according to an eighth working example as shown in FIG. 26 obtained by changing a single-layer metal film in the seventh working example to a multi-layer metal film was used to examine an effect caused by providing a multi-layer metal film. FIG. 26 is a diagram for describing the details of this simulation. Au and Cr were selected to form a multi-layer metal film. Specifically, in the end surface incident-type light receiving element according to the eighth working example, a first metal film made of Cr was layered on the dielectric film, and a second metal film made of Au was layered on the first working example. The conditions for the absolute refractive indices of the semiconductor material and air were set to be the same as those in the above-mentioned first simulation. The complex refractive index of the first metal film (Cr) was set to “3.6-3.6×j”, and the absolute refractive index of the second metal film (Au) was set to be the same as that described above.

Under these conditions, the reflectance of the inclined surface was calculated in a fifth case where the dielectric film (SiO₂) had a thickness of 100 nm and a sixth case where the dielectric film had a thickness of 10 nm while the thicknesses of the first metal film (Cr) and the second metal film (Au) were changed as appropriate. It should be noted that the light incident angle C was set to 14.2 degrees as in the cases described above, and the light wavelength was set to 1550 nm.

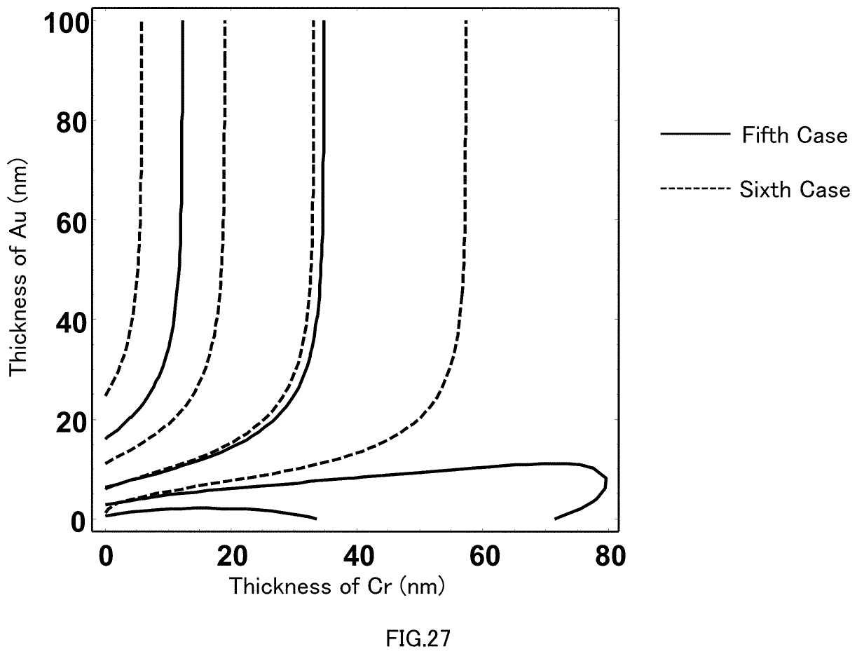

FIG. 27 shows the results of a contour plot of the reflectance relative to the thicknesses of the first metal film (Cr) and the second metal film (Au) when the light incident angle C was 14.2 degrees. It was found from the results shown in FIG. 27 that, in both cases, the reflectance of the inclined surface could be improved to 90% or more by setting the thickness of the first metal film (Cr) to 10 nm or smaller and the thickness of the second metal film (Au) to 30 nm or larger.

It was thus found that, even when the thickness of the metal film made of Au is reduced compared with the above-mentioned seventh working example, forming a metal film made of Cr with a thickness of 10 nm or less makes it possible to improve the reflectance of the inclined surface to 90% or more. In other words, it was found that, when a metal film is provided to improve the reflectance of the inclined surface, using less expensive metal makes it possible to reduce the usage amount of more expensive metal. Therefore, it was found that, compared with the case where a single-layer metal film is provided, providing a multi-layer metal film makes it possible to reduce the manufacturing cost of the end surface incident-type light receiving element without a decrease in the coupling efficiency.

It should be noted that the complex refractive index of Ti is “3.6−3.5×j”, which is substantially the same as the complex refractive index of Cr, and therefore, similar results can be obtained if the material of the first metal layer is changed from Cr to Ti. It was thus found that, when a multi-layer metal layer is provided on the outer side of the inclined surface, using Cr or Ti as the material of the first metal layer is effective from the viewpoint of the manufacturing cost.

### LIST OF REFERENCE NUMERALS

100 . . . End surface incident-type light receiving element,
10 . . . n-type InP substrate, 11 . . . Active layer,
12 . . . n-type InP layer, 13 . . . p-type diffusion region,
15 . . . Active region,
18 . . . p-type electrode, 19 . . . n-type electrode,
21 . . . Upper surface, 211 . . . End portion,
22 . . . Lower surface, 221 . . . End portion,
23 . . . End surface, 24 . . . Back surface,
31 . . . Groove, 32 . . . Inclined surface, 33 . . . Upper end,
34 . . . Dielectric film, 35 . . . Metal film,
90 . . . Semiconductor laser device, 91 . . . Light emitting point,
92 . . . Laser beam

1. An end surface incident-type light receiving element made of a semiconductor material, comprising:
an upper surface and a lower surface that are opposite to each other in a vertical direction; and
an end surface that couples the upper surface and the lower surface and is to be arranged on a light source side, the side being a side from which the light source emits light,
wherein at least a portion of the end surface is inclined relative to the vertical direction in a state in which a portion on the lower surface side of the inclined portion is arranged closer to the light source than a portion on the upper surface side of the inclined portion is,
the lower surface is provided with one or more grooves,
inclined surfaces on the end surface side of the one or more grooves are arranged so as to reflect incident light that is emitted from the light source and passes through the end surface, and
a light receiving region for receiving the light reflected by the inclined surfaces on the end surface side of the one or more grooves is provided on the upper surface side.

2. The end surface incident-type light receiving element according to claim 1,
wherein the entire region of the end surface is inclined relative to the vertical direction.

3. The end surface incident-type light receiving element according to claim 1,
wherein a portion on the upper surface side of the end surface is inclined relative to the vertical direction, and the remainder of the end surface is formed extending in the vertical direction.

4. The end surface incident-type light receiving element according to claim 3,
a lower end of the inclined portion on the upper surface side is located at a position that is as high as upper ends of the one or more grooves or is higher than upper ends of the one or more grooves.

5. The end surface incident-type light receiving element according to claim 3,
wherein an inclination angle A1 of the inclined portion on the upper surface side and inclination angles A2 of the inclined surfaces of the one or more grooves are set to satisfy Formula 1:
$$A 2 \leq A 1 + {sin}^{- 1} ( \frac{{n}_{1}}{{n}_{2}} \cdot cos A 1 ) - {sin}^{- 1} ( \frac{{n}_{1}}{{n}_{2}} ) \qquad Formula 1$$
where n₁ indicates the absolute refractive index of air, and n₂ indicates the absolute refractive index of the semiconductor material.

6. The end surface incident-type light receiving element according to claim 1,
wherein the portion of the end surface that is inclined relative to the vertical direction is formed in a flat shape.

7. The end surface incident-type light receiving element according to claim 1,
wherein the portion of the end surface that is inclined relative to the vertical direction is formed in a curved shape to condense the incident light emitted from the light source on at least one of the inclined surfaces on the end surface side of the one or more grooves.

8. The end surface incident-type light receiving element according to claim 1,
wherein the lower surface is provided with a plurality of the grooves, and
the plurality of the grooves are arranged in a direction in which the light is incident.

9. The end surface incident-type light receiving element according to claim 1,
wherein a metal film is formed on the outer sides of the inclined surfaces on the end surface side of the one or more grooves.
